(19) United States
(12) Patent Application Publication
(10) Pub. No.: US 2024/0372936 A1
(43) Pub. Date: Nov. 7, 2024

(54) SUPPORT STRUCTURE AND ELECTRONIC DEVICE COMPRISING SAME

(71) Applicant: SAMSUNG ELECTRONICS CO., LTD., Suwon-si (KR)

(72) Inventors: Sangyup LEE, Suwon-si (KR); Dongyoon OH, Suwon-si (KR)

(21) Appl. No.: 18/779,083

(22) Filed: Jul. 22, 2024

Related U.S. Application Data
(63) Continuation of application No. PCT/KR2023/001197, filed on Jan. 26, 2023.

(30) Foreign Application Priority Data
Feb. 8, 2022 (KR) 10-2022-0016524

(51) Int. Cl. H04M 1/02; H05K 1/14

(52) U.S. Cl. CPC H04M 1/0277; H04M 1/0266; H05K 1/147

(57) ABSTRACT

An electronic device includes: a housing; a display disposed in the housing; a first printed circuit board disposed within the housing; a flexible printed circuit board disposed in the housing and including a first surface and a second surface facing the opposite direction to the first surface; a connector connecting the first surface of the flexible printed circuit board with the first printed circuit board; a reinforcing member coupled to the second surface and disposed to face the connector with the flexible printed circuit board interposed therebetween; a support member disposed between the first surface and the first printed circuit board, and having at least a portion facing the reinforcing member with the flexible printed circuit board interposed therebetween; a first adhesive member adhering the support member and the first surface; and a second adhesive member adhering the support member and the first printed circuit board.

### CROSS-REFERENCE TO RELATED APPLICATIONS

This application is a continuation application, claiming priority under § 365 (c), of an International application No. PCT/KR2023/001197, filed on Jan. 26, 2023, which is based on and claims the benefit of a Korean patent application number 10-2022-0016524, filed on Feb. 8, 2022, in the Korean Intellectual Property Office, the disclosure of each of which is incorporated by reference herein in its entirety.

### TECHNICAL FIELD

Various embodiments disclosed herein relate to an electronic device, for example, a support structure and an external electronic device including the same.

### BACKGROUND ART

Electronic devices may output information stored therein as sound or an image. With the increase of degree of integration of electronic devices and the generalization of ultra-high-speed and high-capacity wireless communication, recently, various functions are capable of being provided in a single electronic device, such as a mobile communication terminal. For example, in addition to communication functions, entertainment functions such as games, multimedia functions such as music/video playback, communication and security functions for mobile banking or the like, schedule management functions, and electronic wallet functions, are being integrated into a single electronic device.

Portable electronic devices such as smartphones and tablet PCs continue to be widely distributed, and technology for pen input devices applicable to portable electronic devices is also being actively developed. Smartphones or tablet PCs are usually equipped with a touch screen, and a user may specify specific coordinates of the touch screen with a finger or a pen-type input device. A user may input specific signals into a smartphone or a tablet PC by specifying specific coordinates on the touch screen.

### SUMMARY

### Technical Problem

In general, an electronic device may be equipped with various electrical components and include a signal transmission member such that signals can be exchanged between the various electrical components. The signal transmission member may include a cable or a flexible printed circuit board (PCB).

The flexible printed circuit board may connect a printed circuit board and electrical components or connect printed circuit boards that are spaced apart from each other. The flexible printed circuit board may be electrically and/or physically connected to a printed circuit board via a connector.

An electronic device may be subject to shock directly or indirectly during use, and the shock applied to the electronic device may be transmitted to components within the electronic device. In this case, there is a concern that the flexible printed circuit board may be separated from the connector due to the shock applied to the electronic device.

Various embodiments of the disclosure are able to provide a support structure capable of preventing a flexible printed circuit board from being separated from a connector and an electronic device including the same.

However, the problems to be solved in the disclosure are not limited to the above-mentioned problems, and may be variously expanded without departing from the spirit and scope of the disclosure.

### Technical Solution

According to various embodiments of the disclosure, an electronic device may include: a housing; a display disposed in the housing; a first printed circuit board disposed within the housing; a flexible printed circuit board disposed within the housing, where the flexible printed circuit board includes a first surface and a second surface opposite to the first surface; a connector configured to connect at least a portion of the first surface of the flexible printed circuit board and the first printed circuit board; a reinforcement member coupled to the second surface of the flexible printed circuit board, where at least a portion of the reinforcement member is disposed to face the connector with the flexible printed circuit board interposed therebetween; a support member disposed between the first surface of the flexible printed circuit board and the first printed circuit board, where at least a portion of the support member is disposed to face the reinforcement member with the flexible printed circuit board interposed therebetween; a first adhesive member configured to adhere the support member and the first surface of the flexible printed circuit board to each other; and a second adhesive member configured to adhere the support member and the first printed circuit board to each other.

According to various embodiments of the disclosure, an electronic device may include: a housing; a display disposed in the housing and including a touch sensor and a display panel; a first printed circuit board electrically connected to the touch sensor; a second printed circuit board spaced apart from the first printed circuit board and electrically connected to the display panel; a flexible printed circuit board disposed within the housing and including a first portion electrically connected to the first printed circuit board; and a second portion extending from the first portion and electrically connected to the second printed circuit board; a connector configured to connect the first printed circuit board and the first portion; a reinforcement member coupled to the first portion, where at least a portion of the reinforcement member is disposed to face the connector with the first portion interposed therebetween; a support member disposed between the flexible printed circuit board and the first printed circuit board, where at least a portion of the support member is disposed to face the reinforcement member with the first portion interposed therebetween; a first adhesive member configured to adhere the support member and the first surface of the flexible printed circuit board to each other; and a second adhesive member configured to adhere the support member and the first printed circuit board to each other.

According to various embodiments of the disclosure, a support structure of a connection circuit board may include: a first printed circuit board; a connector coupled to at least a portion of the first printed circuit board; a flexible printed circuit board including a first portion coupled to the connector and a second portion extending from the first portion; a reinforcement member coupled to the first portion, where at least a portion of the reinforcement member is disposed to face the connector; a support member disposed between the first portion and the first printed circuit board; a first adhesive member configured to adhere the support member and the first portion to each other; and a second adhesive member configured to adhere the support member and the first printed circuit board to each other.

### Advantageous Effects

According to various embodiments of the disclosure, the flexible printed circuit board can be restricted from being separated from the connector.

According to various embodiments of the disclosure, the durability and maintainability of the electronic device can be improved by preventing the connection between the flexible printed circuit board and the first printed circuit board from being released.

According to various embodiments of the disclosure, even when an external force acts on the flexible printed circuit board and the reinforcement member in various directions, the flexible printed circuit board can be restricted from being separated from the connector.

Effects that may be obtained in the disclosure are not limited to those described above, and other effects not described above will be clearly understood by a person ordinarily skilled in the art to which the disclosure belongs based on the following description.

### BRIEF DESCRIPTION OF DRAWINGS

FIG. 1 is a block diagram illustrating an electronic device 101 in a network environment 100 according to various embodiments.

FIG. 2 is a front perspective view illustrating the electronic device according to various embodiments of the disclosure.

FIG. 3 is a rear perspective view of an electronic device according to various embodiments of the disclosure.

FIG. 4 is an exploded perspective view of an electronic device according to various embodiments of the disclosure.

FIG. 5 is a rear view of an electronic device according to various embodiments of the disclosure.

FIG. 6A is a view illustrating the state in which a flexible printed circuit board is coupled to a printed circuit board in an electronic device according to various embodiments of the disclosure.

FIG. 6B is a view illustrating a printed circuit board and a connector of an electronic device according to various embodiments of the disclosure.

FIG. 7 is a cross-sectional view taken along line A-A′ in FIG. 6A according to various embodiments of the disclosure.

FIG. 8A is a view illustrating the state in which a flexible printed circuit board is coupled to a printed circuit board in an electronic device according to various embodiments of the disclosure.

FIG. 8B is a view illustrating the printed circuit board and a connector of the electronic device according to various embodiments of the disclosure.

FIG. 9 is a cross-sectional view taken along line B-B′ in FIG. 6A according to various embodiments of the disclosure.

FIG. 10A is a view illustrating in the state in which a flexible printed circuit board is coupled to a printed circuit board of an electronic device according to various embodiments of the disclosure.

FIG. 10B is a view illustrating the printed circuit board and a connector of the electronic device according to various embodiments of the disclosure.

FIG. 11 is a cross-sectional view taken along line C-C′ in FIG. 6A according to various embodiments of the disclosure.

### DETAILED DESCRIPTION

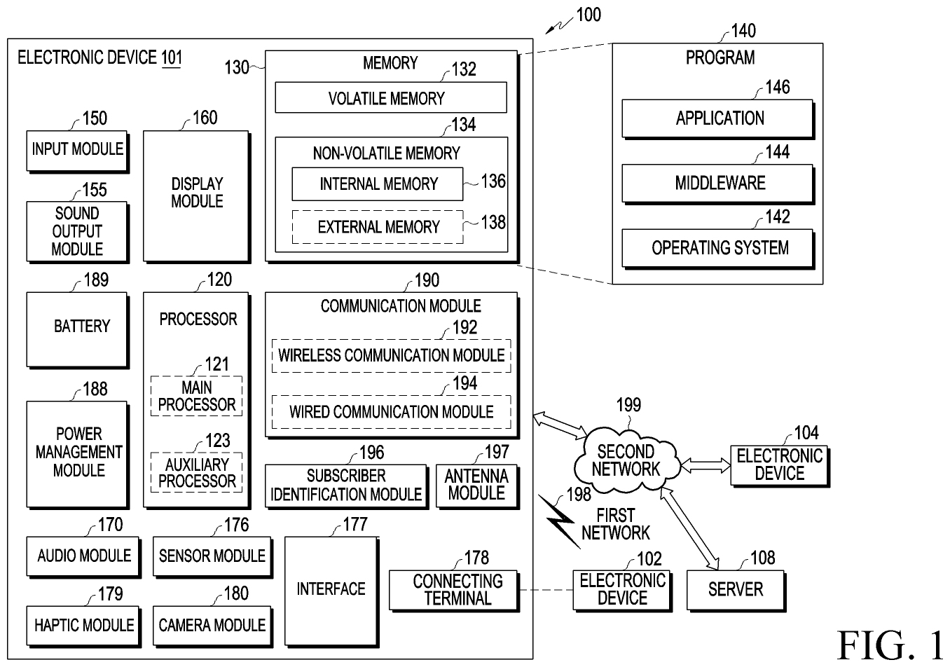

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mm Wave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components.

According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

“substantially equal” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially equal” can mean within one or more standard deviations, or within ±10%, 50% or 2% of the stated value.

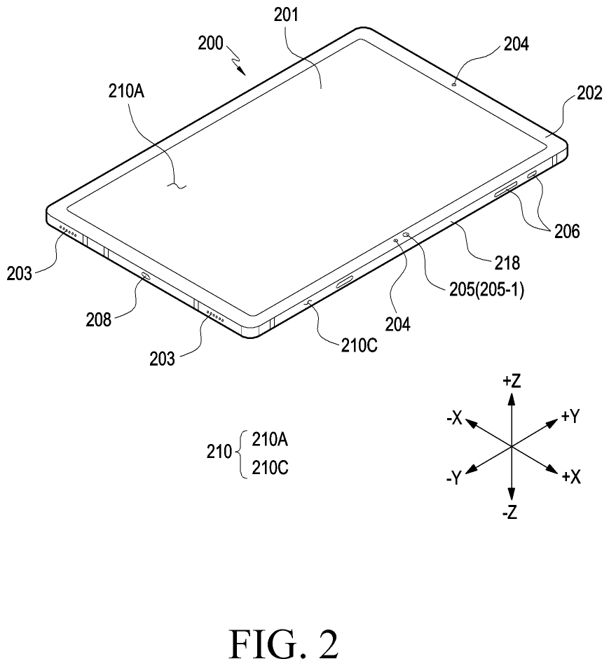

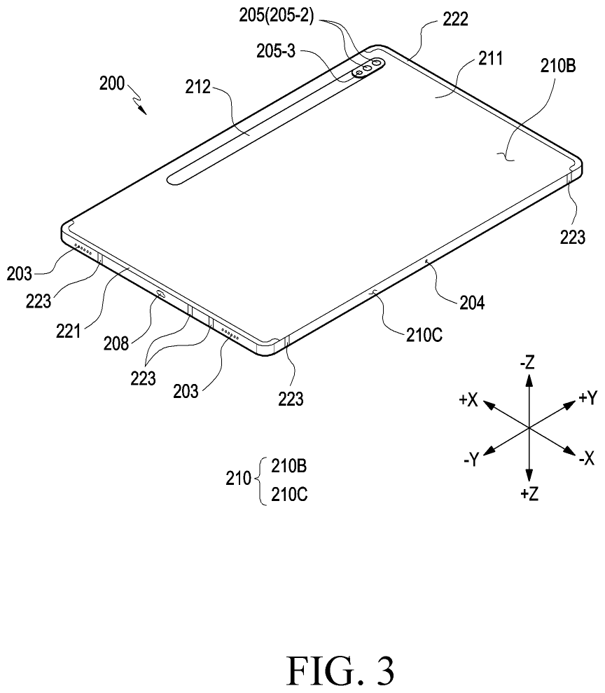

FIG. 2 is a front perspective view illustrating the electronic device according to various embodiments of the disclosure. FIG. 3 is a rear perspective view illustrating the electronic device according to various embodiments of the disclosure.

Hereinafter, for convenience of description with reference to FIGS. 2 to 11, FIGS. 2 to 11 show a spatial coordinate system defined and interpreted as the X, Y, and Z axes orthogonal to each other. Hereinafter, for convenience of description, the X-axis direction may be defined and interpreted as the width direction of an electronic device and its components, the Y-axis direction may be defined and interpreted as the length direction of the electronic device and its components, and the Z-axis direction may be defined and interpreted as the height direction (or thickness direction) of the electronic device and its components.

Referring to FIGS. 2 and 3, an electronic device 200 (e.g., the electronic device 101 in FIG. 1) may include a housing 210 including a first surface (or the front surface) 210A, a second surface (or the rear surface) 210B, and a side surface 210C surrounding the space between the first surface 210A and the second surface 210B. In another embodiment (not illustrated), the term “housing 210” may refer to a structure defining a part of the first surface 210A, the second surface 210B, and the side surface 210C of FIGS. 2A to 3. According to an embodiment, at least a portion of the first surface 210A may be defined by a substantially transparent first plate 202 (e.g., a glass plate or a polymer plate including various coating layers). The second surface 210B may be defined by a substantially opaque second plate 211. The second plate 211 may be made of, for example, coated or colored glass, ceramic, polymer, metal (e.g., aluminum, stainless steel (STS), or magnesium), or at least one or a combination of two or more of these materials. For example, the second plate 211 may be made of a combination of metal and glass. Here, the glass may include a combination of multiple glasses of different colors, materials, and/or textures. The side surface 210C may be defined by a side surface member 218 coupled to the first plate 202 and the second plate 211 and including metal and/or polymer. In some embodiments, the second plate 211 and the side surface member 218 may be integrally configured and may include the same material (e.g., a metal material such as aluminum).

According to an embodiment, the electronic device 200 may include at least one of a display 201, an audio module 203, a sensor module 204, a camera module 205, key input devices 206, and a connector hole 208. In some embodiments, in the electronic device 200, at least one of the components (e.g., the key input devices 206) may be omitted, or other components may be additionally included.

The display 201 may be exposed through, for example, a substantial portion of the first plate 202. According to an embodiment, the display 201 may have a rectangular peripheral shape. In some embodiments, the edges of the display 201 may be configured to be substantially the same as the peripheral shape of the first plate 202 adjacent thereto. In another embodiment (not illustrated), the distance between the periphery of the display 201 and the outer periphery of the first plate 202 may be configured to be substantially constant in order to enlarge the exposed area of the display 201.

The display device 201 may include, for example, a liquid crystal display (LCD), a light-emitting diode (LED) display, an organic light-Emitting diode (OLED) display, a microelectromechanical system (MEMS) display, or an electronic paper display. The display 201 may display various contents (e.g., texts, images, videos, icons, or symbols) to, for example, the user.

In another embodiment (not illustrated), a recess or an opening may be provided in a portion of a screen display area of the display 201, and at least one of an audio module 203, a sensor module 204, and a camera module 205, which are aligned with the recess or the opening, may be included. In another embodiment (not illustrated), the display 201 may be coupled to or disposed adjacent to a pressure sensor capable of measuring a touch intensity (pressure), and/or a digitizer configured to recognize coordinates input by an electromagnetic field-type pen. The display 201 may receive a touch input, a gesture input, a proximity input, or a hovering input that is made using, for example, a pen input device (e.g., a stylus pen) or a portion of the user's body.

The audio module 203 may include a microphone hole and a speaker hole. A microphone configured to acquire external sound may be placed inside the microphone hole. In some embodiments, the microphone hole may include a plurality of microphones disposed at different locations (or different surfaces) of the electronic device to detect the direction of sound. The speaker hole may include an external speaker hole and/or a call receiver hole. In some embodiments, the microphone hole and the speaker hole may be implemented as a single hole, or a speaker (e.g., a piezo speaker) may be included without a speaker hole.

The sensor module 204 may generate electrical signals or data values corresponding to an internal operating state or an external environmental state of the electronic device 200. The sensor module 204 may, for example, be disposed on the first surface 210A or the second surface 210B of housing 210 and, additionally or alternatively, may also be disposed on the side surface 210C. The sensor module may further include at least one of a proximity sensor, a luminance sensor, a biometric sensor, a gesture sensor, a gyro sensor, an atmospheric pressure sensor, a magnetic sensor, an acceleration sensor, a grip sensor, a color sensor, an infrared (IR) sensor, a temperature sensor, and a humidity sensor.

The camera module 205 may include first and second camera devices 205-1 and 2502 disposed on the first and second surfaces 210A and 210B of the electronic device 200, and/or a flash 205-3, and/or a flash 205-3. The camera devices 205-1 and 205-2 may include one or more lenses, an image sensor, and/or an image signal processor. The flash 205-3 may include, for example, a light-emitting diode or a xenon lamp. In some embodiments, two or more lenses (e.g., an infrared camera lens, a wide-angle lens, and a telephoto lens) and image sensors may be disposed on one surface of the electronic device 200.

The key input devices 206 may be disposed on the side surface 210C of the housing 210. In another embodiment, the electronic device 200 may not include some or all of the above-mentioned key input devices 206, and the key input devices 206, which are not included, may be implemented in another form, such as soft keys, on the display 201.

The connector hole 208 may include a connector hole that is capable of accommodating a connector configured to transmit/receive power and/or data to/from an external electronic device (e.g., a USB connector), and/or a connector hole that is capable of accommodating a connector configured to transmit/receive an audio signal to/from an external electronic device (e.g., an earphone jack).

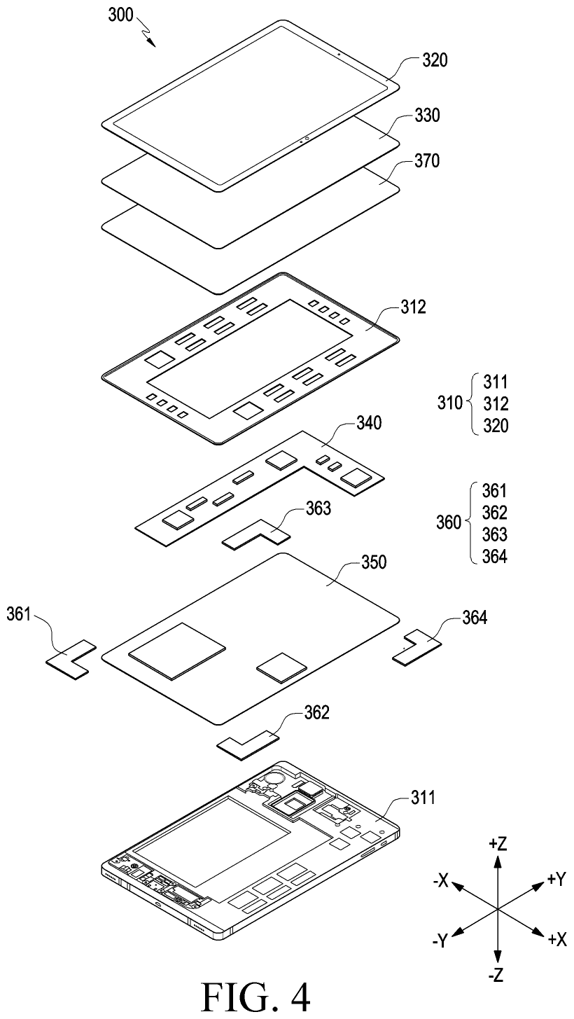

FIG. 4 is an exploded perspective view of an electronic device according to various embodiments of the disclosure.

Referring to FIG. 4, an electronic device 300 may include a housing 310 (e.g., the housing 310 in FIGS. 2 to 3) including a side surface bezel structure 311 (e.g., the side surface member 218 in FIG. 2), a first support member 312 (e.g., a bracket), and a first plate 320 (e.g., the first plate 202 in FIG. 2), a display 330, an electromagnetic induction panel 370, a printed circuit board 340, and a battery 350. According to an embodiment, a second plate (e.g., the second plate 211 in FIG. 3) opposite to the first plate 320 may be integrally integrated with or formed with the side surface bezel structure 311. In some embodiments, in the electronic device 300, at least one of the components (e.g., the first support member 312) may be omitted, or other components may be additionally included. At least one of the components of the electronic device 300 may be the same or similar to at least one of the components of the electronic device 101 of FIG. 1 or the electronic device 200 of FIG. 2, and a redundant description will be omitted below.

The configuration of the side surface bezel structure 311, the first plate 320, and/or the display 330 of FIG. 4 may be wholly or partly the same as the configuration of the side surface member 218, the first plate 202, and/or the display 201 of FIGS. 2 and 3.

According to various embodiments, the electromagnetic induction panel 370 (e.g., a digitizer) may be a panel configured to detect input from a pen input device (not illustrated) (e.g., a stylus pen). For example, the electromagnetic induction panel 370 may include a printed circuit board (e.g., a flexible printed circuit board (FPCB)) and a shield sheet. The shield sheet is capable of preventing interference between components included within the electronic device 300 (e.g., a display module, a printed circuit board, an electromagnetic induction panel, and the like) due to electromagnetic fields generated from the components. By blocking the electromagnetic fields generated from the components, the shield sheet is capable of causing an input from the pen input device to be accurately transmitted to a coil included in the electromagnetic induction panel 370. According to an embodiment, the electromagnetic induction panel 370 may be disposed between the display 330 and the first support member 312. According to another embodiment (not illustrated), the electromagnetic induction panel 370 may be disposed between the first plate 320 and the display 330.

According to various embodiments, the first support member 312 may be disposed inside the electronic device 300 to be connected to the side surface bezel structure 311, or may be formed integrally with the side surface bezel structure 311. The first support member 312 may be made of, for example, a metal material and/or a non-metal (e.g., polymer) material. The first support member 312 may include one surface to which the display 330 is coupled and the other surface to which the printed circuit board 340 is coupled. A processor, memory, and/or an interface may be mounted on the printed circuit board 340. The processor may include one or more of, for example, a central processing unit, an application processor, a graphics processing unit, an image signal processor, a sensor hub processor, or a communication processor.

The memory may include, for example, volatile memory or non-volatile memory.

The interface may include, for example, a high-definition multimedia interface (HDMI), a universal serial bus (USB) interface, an SD card interface, and/or an audio For example, the interface may electrically or physically connect the interface. electronic device 300 to an external electronic device, and include a USB connector, an SD card/MMC connector, or an audio connector.

According to an embodiment, the battery 350 is a device configured to supply power to at least one component of the electronic device 300, and may include, for example, a non-rechargeable primary battery, a rechargeable secondary battery, or a fuel cell. At least a portion of the battery 350 may be disposed to on substantially the same plane as, for example, the printed circuit board 340. The battery 350 may be integrally disposed inside the electronic device 300, or may be detachably disposed on the electronic device 300.

According to various embodiments, the electronic device 300 may further include antennas 361, 362, 363, and 364. Referring to FIGS. 3 and 4 together, at least some of the housing of the electronic device 300 may be used as radiators for the antennas 361, 362, 363, and 364. For example, at least a portion of the frame of the housing can be used as a radiator for an antenna (hereinafter, referred to as a “frame antenna”). The frame antenna may be distinguished from other adjacent frame antennas via a band-shaped antenna injection member (e.g., the injection-molded members 221 and 222 in FIG. 3) and a plurality of slits (e.g., the slit 223 in FIG. 3). According to various embodiments, a 5G mmWave antenna may be accommodated and used inside the housing of the electronic device 300. With an antenna, for example, short-distance communication may be performed with an external device, or power required for charging may be transmitted/received wirelessly.

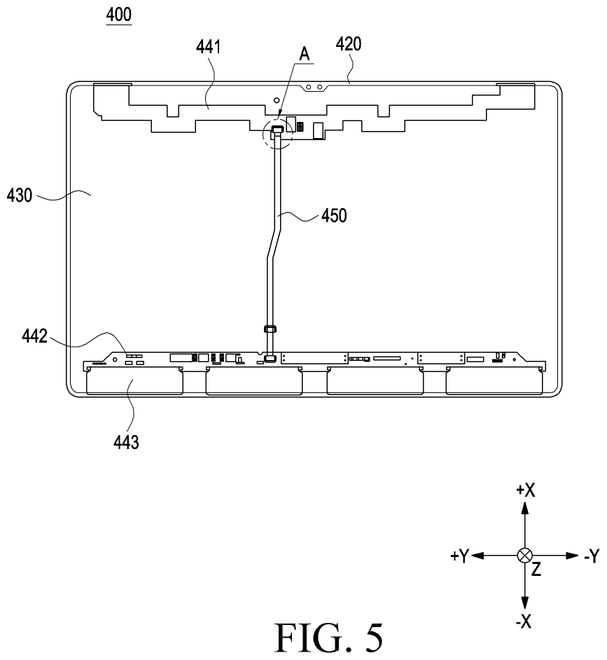

FIG. 5 is a rear view of an electronic device according to various embodiments of the disclosure. The display 430 illustrated in FIG. 5 may be the display 330 of FIG. 4 as viewed from the −Z direction toward the +Z direction in FIG. 4.

Referring to FIG. 5, an electronic device 400 (e.g., the electronic device 300 in FIG. 4) may include a first plate 420, a display 430, a first printed circuit board 441, and a second printed circuit board 442, and/or a flexible printed circuit board 450.

The configuration of the first plate 420 and/or the display 430 of FIG. 5 may be wholly or partly the same as the configuration of the first plate 320 and/or the display 330 of FIG. 4. The configuration of the first printed circuit board 441 and/or the second printed circuit board 442 of FIG. 5 may be wholly or partly the same as that of the printed circuit board 340 of FIG. 4.

According to various embodiments, the display 430 (e.g., the display 330 in FIG. 4) may include a front surface facing the first plate 420 (e.g., the first plate 320 in FIG. 4), and a rear surface opposite to the front surface. According to an embodiment, the rear surface of the display 430 may face a battery (not illustrated) (e.g., the battery 350 in FIG. 4), a first support member (not illustrated) (e.g., the first support member 312 in FIG. 4) and/or a side surface bezel structure (not illustrated) (e.g., the side surface bezel structure 311 in FIG. 4).

According to various embodiments, the electronic device 400 may include a first printed circuit board 441 (e.g., the printed circuit board 340 in FIG. 4) electrically connected to an electromagnetic induction panel (not illustrated) (e.g., the electromagnetic induction panel 370 in FIG. 4) or a touch sensor (not illustrated) of the display 430.

According to various embodiments, the display 430 may be a touch screen panel (TSP) configured to detect input from a user's finger or a pen. According to an embodiment, the display 430 may include a touch sensor (or touch panel) and a display panel. In an embodiment, the display 430 may be an on-cell-type display having a touch sensor (or touch panel) laminated on the display panel. In another embodiment, the display 430 may be an in-cell-type display having a touch sensor built into the display panel. According to some embodiments, the display 430 may have a multi-layer structure including a display panel, a touch sensor (or touch panel), a polarizing plate, or a shield layer. In an embodiment, the touch sensor (or touch panel) may further include a touch display driver IC (TDDI).

According to various embodiments, the electronic device 400 may include a second printed circuit board 442 (e.g., the printed circuit board 340 in FIG. 4) electrically connected to the display panel of the display 430. According to an embodiment, the second printed circuit board 442 may be spaced apart from the first printed circuit board 441. According to an embodiment, the second printed circuit board 442 may be electrically and/or physically connected to the connection panel 443, which is electrically and/or physically connected to the display panel of the display 430. In an embodiment, the connection panel 443 may be an LCD driver IC (LDI) panel.

According to various embodiments, the first printed circuit board 441 and/or the second printed circuit board 442 may be placed within the electronic device 400 or the housing (e.g., the housing 210 in FIGS. 2 and 3 or the housing 310 in FIG. 3) of the electronic device 400. According to an embodiment, the first printed circuit board 441 may be defined and interpreted as a sub-printed circuit board (sub-PCB) or a touch printed circuit board (touch PCB), and the second printed circuit board 442 may be defined or interpreted as a main printed circuit board (main PCB).

According to an embodiment, the first printed circuit board 441 may be electrically connected to the touch sensor of the display 430. According to an embodiment, the second printed circuit board 442 may be electrically connected to the display panel of the display 430. According to some embodiments, the first printed circuit board 441 may be electrically connected to an electromagnetic induction panel (not illustrated) (e.g., the electromagnetic induction panel 370 in FIG. 4).

According to various embodiments, the electronic device 400 may include a flexible printed circuit board (flexible PCB (FPCB)) 450 configured to electrically connect the first printed circuit board 441 and the second printed circuit board 442. According to an embodiment, at least a portion of the flexible printed circuit board 450 may be electrically connected to the first printed circuit board 441, and a remaining other portion may be electrically connected to the second printed circuit board 442. In an embodiment, the flexible printed circuit board may transmit a signal from the first printed circuit board 441 to the second printed circuit board 442 or transmit a signal from the second printed circuit board 442 to the first printed circuit board 441.

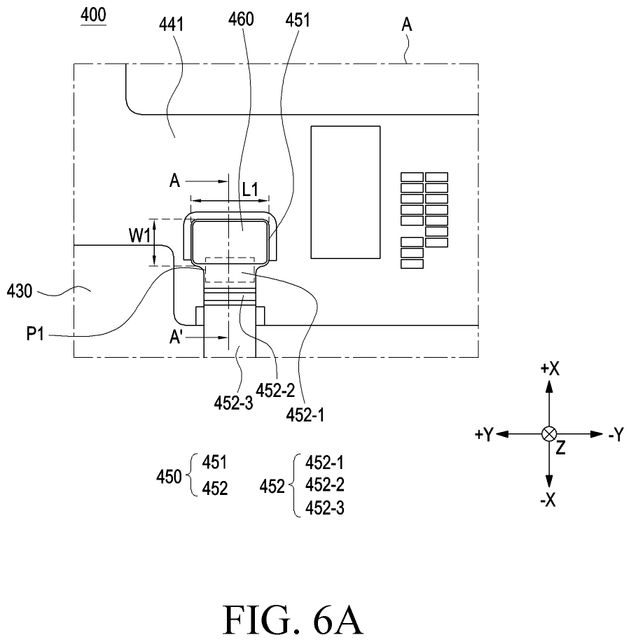

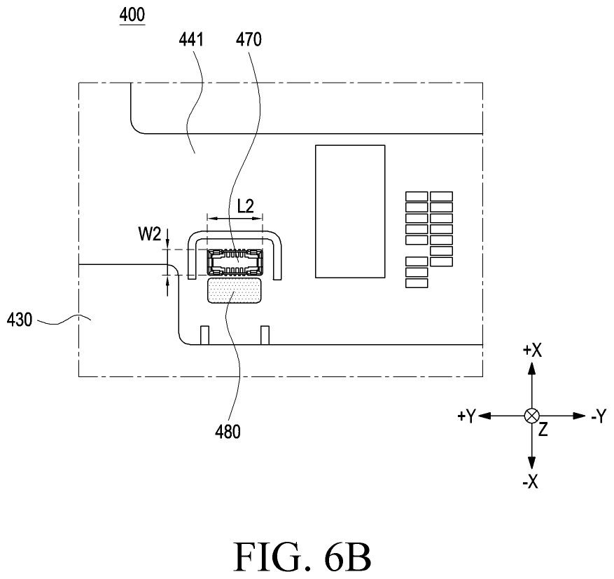

FIG. 6A is a view illustrating the electronic device in the state in which a flexible printed circuit board is coupled to a printed circuit board according to various embodiments of the disclosure. FIG. 6A is an enlarged view of portion A in FIG. 5.

Referring to FIG. 6A, the electronic device 400 (e.g., the electronic device 400 in FIG. 5) may include a display 430, a first printed circuit board 441, a flexible printed circuit board 450, and/or a reinforcement member 460.

The configuration of the display 430, the first printed circuit board 441, and/or the flexible printed circuit board 450 of FIG. 6A may be wholly or partly the same as the configuration of the display 430, the first printed circuit board 441, and/or the flexible printed circuit board 450 of FIG. 5.

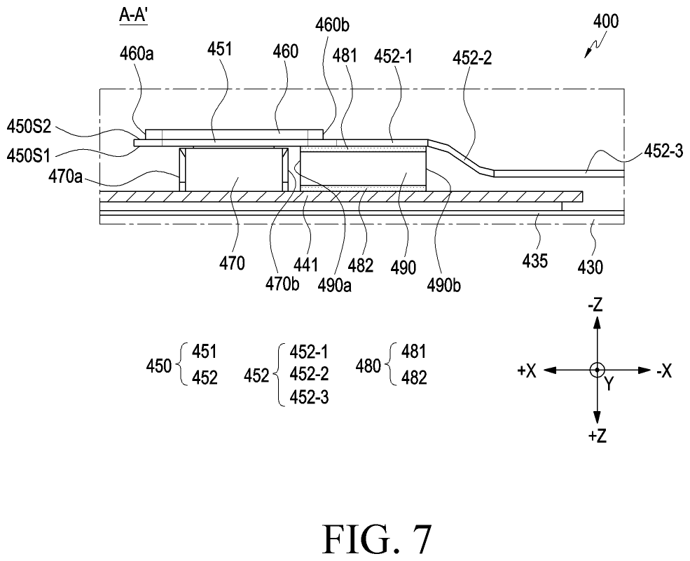

According to various embodiments, the flexible printed circuit board 450 may include a first surface 450S1 and a second surface 450S2 opposite to the first surface 450S1. According to an embodiment, the first surface 450S1 of the flexible printed circuit board 450 may be the surface facing the display 430, and the second surface 450S2 of the flexible printed circuit board 450 may be the surface facing a battery (not illustrated) (e.g., the battery 350 in FIG. 4) and/or the first support member (not illustrated) (e.g., the first support member 312 in FIG. 4). According to an embodiment, the flexible printed circuit board 450 may be connected, in at least a portion of the first surface 450S1 thereof, to the first printed circuit board 441 via a connector (not illustrated) (e.g., the connector 470 in FIG. 6B and/or FIG. 7).

According to various embodiments, the flexible printed circuit board 450 may include a first portion 451 and a second portion 452 extending from the first portion 451 toward the second printed circuit board (not illustrated) (e.g., the second printed circuit board 442 in FIG. 5).

According to various embodiments, the first portion 451 of the flexible printed circuit board 450 may be configured to be connected to the first printed circuit board 441 via the connector (not illustrated) (e.g., the connector 470 in FIG. 6B and/or FIG. 7).

According to various embodiments, the first portion 451 of the flexible printed circuit board 450 may have a first width W1 in a first direction (e.g., the X-axis direction in FIG. 6A), and a first length L1 in a second direction (e.g., the Y-axis direction in FIG. 6A) perpendicular to the first direction (e.g., the X-axis direction in FIG. 6A). According to an embodiment, the first width W1 may be smaller than the first length L1. According to some embodiments (not illustrated), the first width W1 may be substantially equal to or larger than the first length L1.

According to various embodiments, at least a portion of the second portion 452 of the flexible printed circuit board 450 may be configured to be connected to the second printed circuit board (not illustrated) (e.g., the second printed circuit board 442 in FIG. 4).

According to an embodiment, the second portion 452 of the flexible printed circuit board 450 may include a (2-1)^{th} portion 452-1 coupled and/or connected to the first portion 451, a (2-2)^{th} portion 452-2 extending from the (2-1)^{th} portion 452-1, and/or a (2-3)^{th} portion 452-3 extending from the (2-2)^{th} portion 452-2. According to an embodiment, the lengths of the (2-1)^{th} portion 452-1 (minimum length of (2-1)^{th} portion 452-1), the (2-2)^{th} portion 452-2, and the (2-3)^{th} portion 452-3 in a second direction (e.g., the Y-axis direction in FIG. 6A) may be substantially equal to each other.

According to an embodiment, the first surface 450S1 of the flexible printed circuit board 450 may be defined and/or interpreted as the surface facing the display 430 in the first portion 451 and the second portion 452, and the second surface 450S2 of the flexible printed circuit board 450 may be defined and/or interpreted as a surface opposite to the first surface in the first portion 451 and the second portion 452.

According to various embodiments, the electronic device 400 may include a reinforcement member (stiffener) 460 coupled to the second surface 450S2 of the flexible printed circuit board 450. According to an embodiment, the reinforcement member 460 may be coupled to the second surface 450S2 of the first portion 451. According to an embodiment, the reinforcement member 460 may be configured to cover the first portion 451 of the flexible printed circuit board 450, and the reinforcement member 460 may restrict external shock from being directly transferred to the first portion 451 of the flexible printed circuit board 450.

According to various embodiments, the electronic device 400 may further include a support structure (not illustrated) including a support member (not illustrated) (e.g., the support member 490 in FIG. 7) and an adhesive member (not illustrated) (e.g., the adhesive member 480 in FIG. 6B and/or FIG. 7).

According to various embodiments, the support structure (not illustrated) may be disposed between the first surface 450S1 of the flexible printed circuit board 450 and the first printed circuit board 441. According to an embodiment, the support structure (not illustrated) may be disposed in a first space P1 located at a position where the flexible printed circuit board 450 and the first printed circuit board 441 are spaced apart from each other. According to an embodiment, the first space P1 may be a space disposed to extend over at least a portion of the first portion 451 and at least a portion of the 2-1 portion 452-1.

FIG. 6B is a view illustrating a printed circuit board and a connector of an electronic device according to various embodiments of the disclosure. FIG. 6B is a view illustrating the state in which a flexible printed circuit board is removed from the printed circuit board in the electronic device according to various embodiments of the disclosure.

Referring to FIG. 6B, an electronic device 400 (e.g., the electronic device 400 in FIG. 6A) may include a first printed circuit board 441, a display 430, a connector 470, and an adhesive member 480.

The configuration of the first printed circuit board 441 and/or the display 430 of FIG. 6B may be wholly or partly the same as the configuration of the first printed circuit board 441 and/or the display 430 of FIG. 6A.

According to various embodiments, the electronic device 400 may include a connector 470 configured to connect the first printed circuit board 441 and a flexible printed circuit board (not illustrated) (e.g., the flexible printed circuit board 450 in FIG. 6A).

According to various embodiments, the connector 470 may have a second width W2 in a first direction (e.g., the X-axis direction in FIG. 6B), and a second length L2 in a second direction (e.g., the Y-axis direction in FIG. 6B). According to an embodiment, a first width (not illustrated) (e.g., the first width W1 in FIG. 6A) of a first portion (not illustrated) (e.g., the first portion 451 in FIG. 6A) of a flexible printed circuit board (not illustrated) (e.g., the flexible printed circuit board 450 in FIG. 6A) may be larger than the second width W2 of the connector 470.

According to various embodiments, the adhesive member 480 may be disposed between the first printed circuit board 441 and a flexible printed circuit board (not illustrated) (e.g., the flexible printed circuit board 450 in FIG. 6A). According to an embodiment, the adhesive member 480 may be configured to bond the first printed circuit board 441 and the flexible printed circuit board (not illustrated) to each other, and may be disposed in a first space (not illustrated) (e.g., the first space P1 in FIG. 6A). In an embodiment, the adhesive member 480 may be double-sided tape.

FIG. 7 is a cross-sectional view taken along line A-A′ in FIG. 6A according to various embodiments of the disclosure.

Referring to FIG. 7, an electronic device 400 (e.g., the electronic device 400 in FIG. 6A and/or FIG. 6B) may include a display 430, an electromagnetic induction panel 435, a first printed circuit board 441, a flexible printed circuit board 450, a reinforcement member 460, a connector 470, an adhesive member 480, and a support member 490.

The configuration of the display 430 and/or the first printed circuit board 441 in FIG. 7 may be wholly or partly the same as the configuration of the display 430 and/or the first printed circuit board 441 in FIG. 6A and/or FIG. 6B. The configuration of the flexible printed circuit board 450 and/or the reinforcement member 460 of FIG. 7 may be wholly or partly the same as the configuration of the flexible printed circuit board 450 and/or the reinforcement member 460 of FIG. 6A. The configuration of the adhesive member 480 of FIG. 7 may be wholly or partly the same as that of the adhesive member 480 of FIG. 6B. The configuration of the electromagnetic induction panel 435 of FIG. 7 may be wholly or partly the same as that of the electromagnetic induction panel 370 of FIG. 4.

According to various embodiments, the electromagnetic induction panel 435 may be disposed between the first printed circuit board 441 and the display 430. According to some embodiments (not illustrated), the electromagnetic induction panel 435 may be disposed to face the first printed circuit board 441 with the display 430 interposed therebetween.

According to various embodiments, the connector 470 may be configured to connect at least a portion of the first surface 450S1 (e.g., the surface oriented in the +Z direction in FIG. 7) of the flexible printed circuit board 450 and the first printed circuit board 441. According to an embodiment, the connector 470 may be configured to electrically connect the first portion 451 of the flexible printed circuit board 450 and the first printed circuit board 441. In an embodiment, a plug connector may be disposed on the first portion 451 of the flexible printed circuit board 450, and the connector 470 may include a receptacle connector to be fastened to the plug connector disposed on the first portion 451 of the flexible printed circuit board 450. In another embodiment, the connector 470 may include a board-to-board (B-to-B) connector.

According to various embodiments, the reinforcement member 460 may be coupled to the second surface 450S2 (e.g., the surface oriented in the −Z direction in FIG. 7) of the flexible printed circuit board 450. According to an embodiment, the reinforcement member 460 may be coupled to the first portion 451 of the flexible printed circuit board 450, and may be disposed to face the connector 470 with the flexible printed circuit board 450 interposed therebetween.

According to various embodiments, the reinforcement member 460 may extend in a first direction (e.g., the X-axis direction in FIG. 7) including a (1-1)^{th} direction (e.g., the +X direction in FIG. 7) and a (1-2) th direction (e.g., the −X direction in FIG. 7) opposite to the (1-1)^{th} direction (e.g., +X-axis direction in FIG. 7). According to an embodiment, the reinforcement member 460 may include a first edge 460a oriented in the (1-1)^{th} direction (e.g., the +X direction in FIG. 7) and a second edge 460b oriented in the (1-2)^{th} direction (e.g., the −X direction in FIG. 7).

According to various embodiments, the flexible printed circuit board 450 may include a first portion 451 configured to be connected to the connector 470, and a second portion 452 extending from the first portion 451 toward the second printed circuit board (not illustrated) (e.g., the second printed circuit board 442 in FIG. 5). According to an embodiment, the second portion 452 may include a (2-1)^{th} portion 452-1 extending from the first portion 451, a (2-2)^{th} portion 452-2 extending from the (2-1)^{th} portion 452-1 obliquely to approach the display 430, and a (2-3)^{th} portion 452-3 extending from the (2-2)^{th} portion 452-2 substantially in parallel to the display 430. According to an embodiment, the second portion 452 of the flexible printed circuit board 450 may be electrically and/or physically connected, in at least a portion (e.g., the (2-3)^{th} portion 452-3), to the second printed circuit board (not illustrated) (e.g., the second printed circuit board 442 in FIG. 5).

According to various embodiments, the connector 470 may include a first side surface 470a oriented in the (1-1)^{th} direction (e.g., the +X direction in in FIG. 7) and a second side surface 470b oriented in the (1-2)^{th} direction (e.g., the −X direction in FIG. 7). According to various embodiments, at least one of the first side surface 470a and the second side surface 470b may be disposed between the first edge 460a and the second edge 460b with reference to the first direction (e.g., the X-axis direction in FIG. 7). According to an embodiment, the first side surface 470a and the second side surface 470b may be disposed between the first edge 460a and the second edge 460b.

According to various embodiments, the support member 490 may be disposed between a first surface 450S1 (e.g., the surface oriented in the −Z direction in FIG. 7) of the flexible printed circuit board 450 and the first printed circuit board 441. According to an embodiment, at least a portion of the support member 490 may be disposed to face the reinforcement member 460 with the flexible printed circuit board 450 interposed therebetween. According to an embodiment, the support member 490 may include at least one of a Poron member, a silicone member, a rubber member, or a sponge member (i.e., insulating material).

According to various embodiments, the adhesive member 480 may include a first adhesive member 481 and/or a second adhesive member 482. According to an embodiment, the first adhesive member 481 may be configured to bond the support member 490 and the first surface 450S1 (e.g., the surface oriented in the +Z direction in FIG. 7) of the flexible printed circuit board 450. In an embodiment, the first adhesive member 481 may include at least one of adhesive tape or double-sided tape. According to an embodiment, the second adhesive member 482 may be configured to bond the support member 490 and the first printed circuit board 441 to each other. In an embodiment, the second adhesive member 482 may include at least one of adhesive tape or double-sided tape.

According to an embodiment, the first portion 451 may have a first thickness in a third direction (e.g., the Z-axis direction in FIG. 7) perpendicular to the first direction (e.g., the X-axis direction in FIG. 7) and the second direction (e.g., the Y-axis direction in FIG. 7), and the connector 470 may have a second thickness in the third direction (e.g., the Z-axis direction in FIG. 7). In an embodiment, the second thickness may be larger than the first thickness.

According to an embodiment, sum of the thicknesses of the support member 490, the first adhesive member 481, and the second adhesive member 482 in the third direction (e.g., the Z-axis direction in FIG. 7) may be substantially equal to the second thickness.

According to various embodiments, at least a portion of the support member 490 may be disposed between the second edge 460b and the second side surface 470b. According to an embodiment, the support member 490 may include a third side surface 490a oriented in the (1-1)^{th} direction (e.g., the +X direction in FIG. 7) and spaced apart from the second side surface 470b and a fourth side surface 490b oriented in the (1-2)^{th} direction (e.g., the −X direction in FIG. 7). According to an embodiment, the third side surface 490a may be disposed between the second edge 460b and the second side surface 470b, and the fourth side surface 490b may be disposed between the second portion 452 and the first printed circuit board 441. For example, the fourth side surface 490b may be disposed between the (2-1)^{th} portion 452-1 and the first printed circuit board 441.

According to an embodiment, the first adhesive member 481 may be configured to bond at least a portion of one surface (e.g., the surface oriented in the −Z direction in FIG. 7) of the support member 490 to the first portion 451 and the second portion 452.

According to an embodiment, the second adhesive member 482 may be configured to bond at least a portion of the other surface (e.g., the surface oriented in the +Z direction in FIG. 7) of the support member 490 to the first printed circuit board 441.

According to an embodiment, the support member 490 may be disposed between the connector 470 and a second printed circuit board (not illustrated) (e.g., the second printed circuit board 442 in FIG. 5). According to an embodiment, the third side surface 490a of the support member 490 may be disposed to face the connector 470. According to an embodiment, the fourth side surface 490b of the support member 490 may be disposed to face the second printed circuit board (not illustrated) (e.g., the second printed circuit board 442 in FIG. 5).

According to various embodiments, the support structure including the support member 490 and the adhesive member 480 may restrict the flexible printed circuit board 450 from being separated and/or detached from the connector 470.

For example, when an external force acts on a first region of the reinforcement member 460 that does not overlap the connector 470 (e.g., the region of the reinforcement member 460 located between the first edge 460a and the first side surface 470a in FIG. 7) in a (3-1)^{th} direction (e.g., the +Z direction in FIG. 7), a force may act to lift a second region of the reinforcement member 460 that does not overlap the connector 470 (e.g., the region of the reinforcement member 460 located between the second edge 460b and the second side surface 470b in FIG. 7) and the first portion 451 coupled to the same, in the (3-2)^{th} direction (e.g., the −Z direction in FIG. 7). At this time, the support member 490 may be maintained in the state of being fixed to the first printed circuit board 441 by the second adhesive member 482, and the first adhesive member 481 may restrict the second region of the reinforcement member 460 and the first portion 451 coupled to the same from being lifted. Accordingly, the flexible printed circuit board 450 and the first portion 451 of the flexible printed circuit board 450 may be restricted from being separated from the connector 470.

For example, when an external force acts on the second region of the reinforcement member 460 that does not overlap the connector 470 (e.g., the region of the reinforcement member 460 located between the second edge 460b and the second side surface 470b in FIG. 7) in the (3-1)^{th} direction (e.g., the +Z direction in FIG. 7), a force may act to lift the first region of the reinforcement member 460 that does not overlap the connector 470 (e.g., the region of the reinforcement member 460 located between the first edge 460a and the first side surface 470a in FIG. 7) and the first portion 451 coupled to the same, in the (3-2)^{th} direction (e.g., the −Z direction in FIG. 7). At this time, the support member 490 may restrict the first region of the reinforcement member 460 and the first portion 451 coupled to the same from being lifted by supporting the second region of the reinforcement member 460 and the first portion 451 coupled to the same being pressed in the (3-1)^{th} direction (e.g., the +Z direction in FIG. 7). Accordingly, the flexible printed circuit board 450 and the first portion 451 of the flexible printed circuit board 450 may be restricted from being separated from the connector 470.

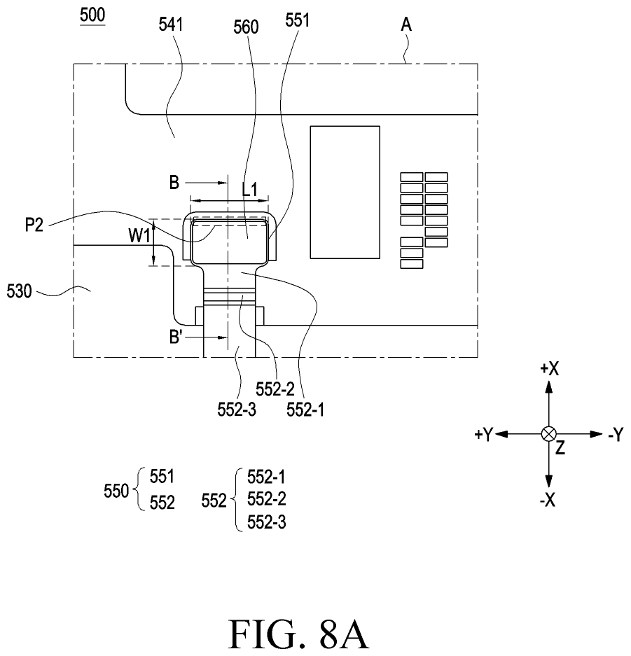

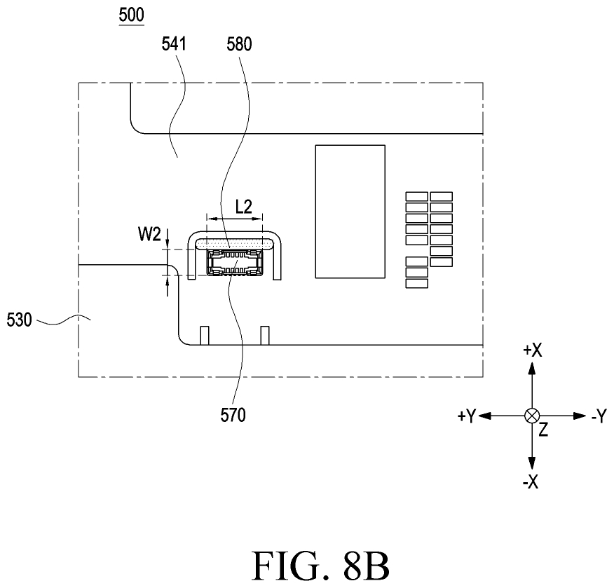

FIG. 8A is a view illustrating the state in which a flexible printed circuit board is coupled to a printed circuit board in an electronic device according to various embodiments of the disclosure. FIG. 8A is another enlarged view of portion A in FIG. 5.

Referring to FIG. 8A, an electronic device 500 (e.g., the electronic device 400 in FIG. 5) may include a display 530, a first printed circuit board 541, a flexible printed circuit board 550, and/or a reinforcement member 560.

The configuration of the display 530, the first printed circuit board 541, and/or the flexible printed circuit board 550 of FIG. 8A may be wholly or partly the same as the configuration of the display 430, the first printed circuit board 441, and/or the flexible printed circuit board 450 of FIG. 5.

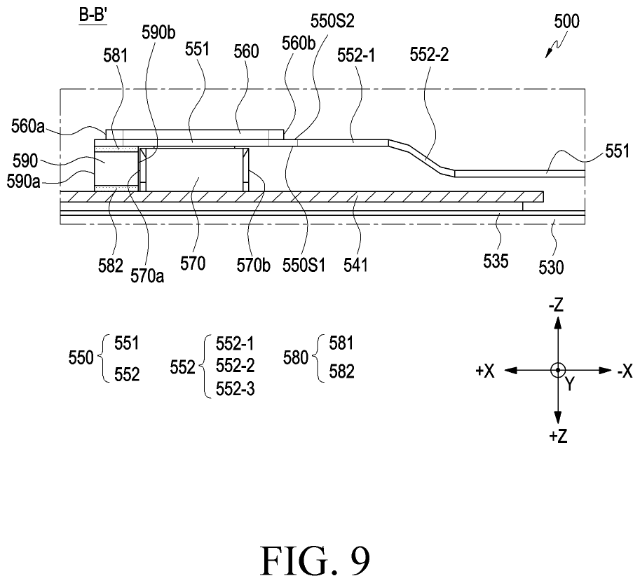

According to various embodiments, the flexible printed circuit board 550 may include a first surface 550S1 and a second surface 550S2 opposite to the first surface 550S1. According to an embodiment, the first surface 550S1 of the flexible printed circuit board 550 may be the surface facing the display 530, and the second surface 550S2 of the flexible printed circuit board 550 may be the surface facing a battery (not illustrated) (e.g., the battery 350 in FIG. 4) and/or the first support member (not illustrated) (e.g., the first support member 312 in FIG. 4). According to an embodiment, the flexible printed circuit board 550 may be connected, in at least a portion of the first surface 550S1 thereof, to the first printed circuit board 541 via a connector (not illustrated) (e.g., the connector 570 in FIG. 8B and/or FIG. 9).

According to various embodiments, the flexible printed circuit board 550 may include a first portion 551 and a second portion 552 extending from the first portion 551 toward the second printed circuit board (not illustrated) (e.g., the second printed circuit board 442 in FIG. 5).

According to various embodiments, the first portion 551 of the flexible printed circuit board 550 may be configured to be connected to the first printed circuit board 541 via the connector (not illustrated) (e.g., the connector 570 in FIG. 8B and/or FIG. 9).

According to various embodiments, the first portion 551 of the flexible printed circuit board 550 may have a first width W1 in a first direction (e.g., the X-axis direction in FIG. 8A), and a first length L1 in a second direction (e.g., the Y-axis direction in FIG. 8A) perpendicular to the first direction (e.g., the X-axis direction in FIG. 8A). According to an embodiment, the first width W1 may be smaller than the first length L1. According to some embodiments (not illustrated), the first width W1 may be substantially equal to or larger than the first length L1.

According to various embodiments, at least a portion of the second portion 552 of the flexible printed circuit board 550 may be configured to be connected to the second printed circuit board (not illustrated) (e.g., the second printed circuit board 542 in FIG. 4).

According to an embodiment, the second portion 552 of the flexible printed circuit board 550 may include a (2-1)^{th} portion 552-1 coupled and/or connected to the first portion 551, a (2-2)^{th} portion 552-2 extending from the (2-1)^{th} portion 552-1, and/or a (2-3)^{th} portion 552-3 extending from the (2-2)^{th} portion 552-2. According to an embodiment, the lengths of the (2-1)^{th} portion 552-1 (minimum length of (2-1)^{th} portion 552-1), the (2-2)^{th} portion 552-2, and the (2-3)^{th} portion 552-3 in a second direction (e.g., the Y-axis direction in FIG. 8A) may be substantially equal to each other.

According to an embodiment, the first surface 550S1 of the flexible printed circuit board 550 may be defined and/or interpreted as the surface facing the display 530 in the first portion 551 and the second portion 552, and the second surface 550S2 of the flexible printed circuit board 550 may be defined and/or interpreted as a surface opposite to the first surface 550S1 in the first portion 551 and the second portion 552.

According to various embodiments, the electronic device 500 may include a reinforcement member (stiffener) 560 coupled to the second surface 550S2 of the flexible printed circuit board 550. According to an embodiment, the reinforcement member 560 may be coupled to the second surface 550S2 of the first portion 551. According to an embodiment, the reinforcement member 560 may be configured to cover the first portion 551 of the flexible printed circuit board 550, and the reinforcement member 560 may restrict external shock from being directly transferred to the first portion 551 of the flexible printed circuit board 550.

According to various embodiments, the electronic device 500 may further include a support structure (not illustrated) including a support member (not illustrated) (e.g., the support member 590 in FIG. 9) and an adhesive member (not illustrated) (e.g., the adhesive member 580 in FIG. 8B and/or FIG. 9).

According to various embodiments, the support structure (not illustrated) may be disposed between the first surface 550S1 of the flexible printed circuit board 550 and the first printed circuit board 541. According to an embodiment, the support structure (not illustrated) may be disposed in a second space P2 located at a position where the flexible printed circuit board 550 and the first printed circuit board 541 are spaced apart from each other. According to an embodiment, the second space P2 may be a space between at least a portion of the first portion 551 and the first printed circuit board 541.

FIG. 8B is a view illustrating the printed circuit board and the connector of the electronic device according to various embodiments of the disclosure. FIG. 8B is a view illustrating the state in which a flexible printed circuit board is removed from the printed circuit board in the electronic device according to various embodiments of the disclosure.

Referring to FIG. 8B, an electronic device 500 (e.g., the electronic device 500 in FIG. 8A) may include a first printed circuit board 541, a display 530, a connector 570, and an adhesive member 580.

The configuration of the first printed circuit board 541 and/or the display 530 of FIG. 8B may be wholly or partly the same as the configuration of the first printed circuit board 541 and/or the display 530 of FIG. 8A.

According to various embodiments, the electronic device 500 may include a connector 570 configured to connect the first printed circuit board 541 and a flexible printed circuit board (not illustrated) (e.g., the flexible printed circuit board 550 in FIG. 8A).

According to various embodiments, the connector 570 may have a second width W2 in a first direction (e.g., the X-axis direction in FIG. 8B), and a second length L2 in a second direction (e.g., the Y-axis direction in FIG. 8B). According to an embodiment, a first width (not illustrated) (e.g., the first width W1 in FIG. 8A) of a first portion (not illustrated) (e.g., the first portion 551 in FIG. 8A) of a flexible printed circuit board (not illustrated) (e.g., the flexible printed circuit board 550 in FIG. 8A) may be larger than the second width W2 of the connector 570.

According to various embodiments, the adhesive member 580 may be disposed between the first printed circuit board 541 and a flexible printed circuit board (not illustrated) (e.g., the flexible printed circuit board 550 in FIG. 8A). According to an embodiment, the adhesive member 580 may be configured to bond the first printed circuit board 541 and the flexible printed circuit board (not illustrated) to each other, and may be disposed in a second space (not illustrated) (e.g., the second space P2 in FIG. 8A). In an embodiment, the adhesive member 580 may be double-sided tape.

FIG. 9 is a cross-sectional view taken along line B-B′ in FIG. 8A according to various embodiments of the disclosure.

Referring to FIG. 9, an electronic device 500 (e.g., the electronic device 500 in FIG. 8A and/or FIG. 8B) may include a display 530, an electromagnetic induction panel 535, a first printed circuit board 541, a flexible printed circuit board 550, a reinforcement member 560, a connector 570, an adhesive member 580, and a support member 590.

The configuration of the display 530 and/or the first printed circuit board 541 in FIG. 9 may be wholly or partly the same as the configuration of the display 530 and/or the first printed circuit board 541 in FIG. 8A and/or FIG. 8B. The configuration of the flexible printed circuit board 550 and/or the reinforcement member 560 of FIG. 9 may be wholly or partly the same as the configuration of the flexible printed circuit board 550 and/or the reinforcement member 560 of FIG. 8A. The configuration of the adhesive member 580 of FIG. 9 may be wholly or partly the same as that of the adhesive member 580 of FIG. 8B. The configuration of the electromagnetic induction panel 535 of FIG. 9 may be wholly or partly the same as that of the electromagnetic induction panel 370 of FIG. 4.

According to various embodiments, the electromagnetic induction panel 535 may be disposed between the first printed circuit board 541 and the display 530. According to some embodiments (not illustrated), the electromagnetic induction panel 535 may be disposed to face the first printed circuit board 541 with the display 530 interposed therebetween.

According to various embodiments, the connector 570 may be configured to connect at least a portion of the first surface 550S1 (e.g., the surface oriented in the +Z direction in FIG. 9) of the flexible printed circuit board 550 and the first printed circuit board 541. According to an embodiment, the connector 570 may be configured to electrically connect the first portion 551 of the flexible printed circuit board 550 and the first printed circuit board 541. In an embodiment, a plug connector may be disposed on the first portion 551 of the flexible printed circuit board 550, and the connector 570 may include a receptacle connector to be fastened to the plug connector disposed on the first portion 551 of the flexible printed circuit board 550. In another embodiment, the connector 570 may include a board-to-board (B-to-B) connector.

According to various embodiments, the reinforcement member 560 may be coupled to the second surface 550S2 (e.g., the surface oriented in the −Z direction in FIG. 9) of the flexible printed circuit board 550. According to an embodiment, the reinforcement member 560 may be coupled to the first portion 551 of the flexible printed circuit board 550, and may be disposed to face the connector 570 with the flexible printed circuit board 550 interposed therebetween.

According to various embodiments, the reinforcement member 560 may extend in a first direction (e.g., the X-axis direction in FIG. 9) including a (1-1)^{th} direction (e.g., the +X direction in FIG. 9) and a (1-2)^{th} direction (e.g., the −X direction in FIG. 9) opposite to the (1-1)^{th} direction (e.g., +X-axis direction in FIG. 9). According to an embodiment, the reinforcement member 560 may include a first edge 560a oriented in the (1-1)^{th} direction (e.g., the +X direction in FIG. 9) and a second edge 560b oriented in the (1-2)^{th} direction (e.g., the −X direction in FIG. 9).

According to various embodiments, the flexible printed circuit board 550 may include a first portion 551 configured to be connected to the connector 570, and a second portion 552 extending from the first portion 551 toward the second printed circuit board (not illustrated) (e.g., the second printed circuit board 542 in FIG. 5). According to an embodiment, the second portion 552 may include a (2-1)^{th} portion 552-1 extending from the first portion 551, a (2-2)^{th} portion 552-2 extending from the (2-1)^{th} portion 552-1 obliquely to approach the display 530, and a (2-3)^{th} portion 552-3 extending from the (2-2)^{th} portion 552-2 substantially in parallel to the display 530. According to an embodiment, the second portion 552 of the flexible printed circuit board 550 may be electrically and/or physically connected, in at least a portion (e.g., the (2-3)^{th} portion 552-3), to the second printed circuit board (not illustrated) (e.g., the second printed circuit board 542 in FIG. 5).

According to various embodiments, the connector 570 may include a first side surface 570a oriented in the (1-1)^{th} direction (e.g., the +X direction in in FIG. 9) and a second side surface 570b oriented in the (1-2)^{th} direction (e.g., the −X direction in FIG. 9). According to various embodiments, at least one of the first side surface 570a and the second side surface 570b may be disposed between the first edge 560a and the second edge 560b with reference to the first direction (e.g., the X-axis direction in FIG. 9). According to an embodiment, the first side surface 570a and the second side surface 570b may be disposed between the first edge 560a and the second edge 560b.

According to various embodiments, the support member 590 may be disposed between a first surface 550S1 (e.g., the surface oriented in the −Z direction in FIG. 9) of the flexible printed circuit board 550 and the first printed circuit board 541. According to an embodiment, at least a portion of the support member 590 may be disposed to face the reinforcement member 560 with the flexible printed circuit board 550 interposed therebetween. According to an embodiment, the support member 590 may include at least one of a Poron member, a silicone member, a rubber member, or a sponge member (i.e., insulating material).

According to various embodiments, the adhesive member 580 may include a first adhesive member 581 and/or a second adhesive member 582. According to an embodiment, the first adhesive member 581 may be configured to bond the support member 590 and the first surface 550S1 (e.g., the surface oriented in the +Z direction in FIG. 9) of the flexible printed circuit board 550. In an embodiment, the first adhesive member 581 may include at least one of adhesive tape or double-sided tape. According to an embodiment, the second adhesive member 582 may be configured to bond the support member 590 and the first printed circuit board 541 to each other. In an embodiment, the second adhesive member 582 may include at least one of adhesive tape or double-sided tape.

According to an embodiment, the first portion 551 may have a first thickness in a third direction (e.g., the Z-axis direction) perpendicular to the first direction (e.g., the X-axis direction in FIG. 9) and the second direction (e.g., the Y-axis direction in FIG. 9), and the connector 570 may have a second thickness in the third direction (e.g., the Z-axis direction in FIG. 9). In an embodiment, the second thickness may be larger than the first thickness.

According to an embodiment, sum of the thicknesses of the support member 590, the first adhesive member 581, and the second adhesive member 582 in the third direction (e.g., the Z-axis direction in FIG. 9) may be substantially equal to the second thickness.

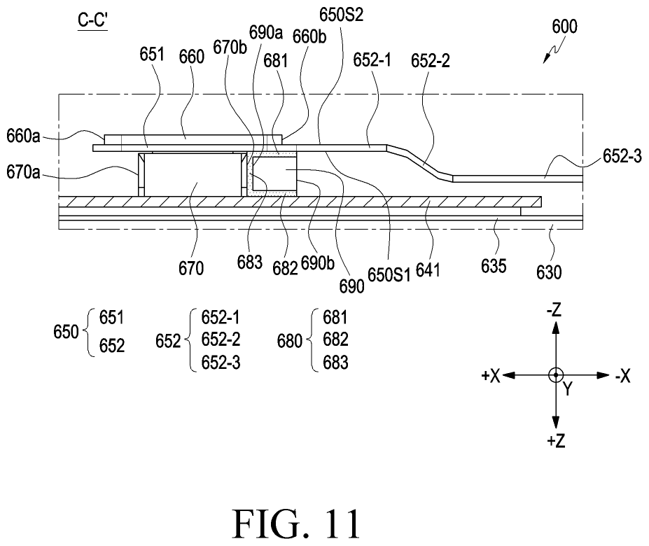

According to various embodiments, at least a portion of the support member 590 may be disposed between the first edge 560a and the first side surface 570a. According to an embodiment, the support member 590 may include a third side surface 590a oriented in the (1-1)^{th} direction (e.g., the +X direction in FIG. 9) and a fourth side surface 590b oriented in the (1-2)^{th} direction (e.g., the −X direction in FIG. 9) and disposed to fact the first side surface 570a. According to an embodiment, the third side surface 590a may be disposed on substantially the same plane as one end edge (e.g., the edge oriented in the −X direction in FIG. 11) of the first portion 551, and the fourth side surface 590b may be disposed between the first edge 560a and the first side surface 570a. For example, the third side surface 590a may be disposed between one end edge of the first portion 551 and the first printed circuit board 541. In an embodiment, the fourth side surface 590b may be disposed adjacent to the first side surface 570a. In another embodiment, the fourth side surface 590b may be connected to or spaced apart from the first side surface 570a.

According to an embodiment, the first adhesive member 581 may be configured to bond at least a portion of one surface (e.g., the surface oriented in the −Z direction in FIG. 9) of the support member 590 to the first portion 551.

According to an embodiment, the second adhesive member 582 may be configured to bond at least a portion of the other surface (e.g., the surface oriented in the +Z direction in FIG. 9) of the support member 590 to the first printed circuit board 541.

According to an embodiment, the connector 570 may be disposed between the support member 590 and a second printed circuit board (not illustrated) (e.g., the second printed circuit board 442 in FIG. 5). According to an embodiment, the first side surface 570a of the connector 570 may be disposed to face the support member 590. According to an embodiment, the second side surface 570b of the connector 570 may be disposed to face the second printed circuit board (not illustrated) (e.g., the second printed circuit board 442 in FIG. 5).

According to various embodiments, the support structure including the support member 590 and the adhesive member 580 may restrict the flexible printed circuit board 550 from being separated and/or detached from the connector 570.

For example, when an external force acts on a first region of the reinforcement member 560 that does not overlap the connector 570 (e.g., the region of the reinforcement member 560 located between the first edge 560a and the first side surface 570a in FIG. 9) in a (3-1)^{th} direction (e.g., the +Z direction in FIG. 9), a force may act to lift a second region of the reinforcement member 560 that does not overlap the connector 570 (e.g., the region of the reinforcement member 560 located between the second edge 560b and the second side surface 570b in FIG. 9) and the first portion 551 coupled to the same, in the (3-2)^{th} direction (e.g., the −Z direction in FIG. 9). At this time, the support member 590 may restrict the second region of the reinforcement member 560 and the first portion 551 coupled to the same from being lifted by supporting the first region of the reinforcement member 560 and the first portion 551 coupled to the same being pressed in the (3-1)^{th} direction (e.g., the +Z direction in FIG. 9). Accordingly, the flexible printed circuit board 550 and the first portion 551 of the flexible printed circuit board 550 may be restricted from being separated from the connector 570.

For example, when an external force acts on the second region of the reinforcement member 560 that does not overlap the connector 570 (e.g., the region of the reinforcement member 560 located between the second edge 560b and the second side surface 570b in FIG. 9) in the (3-1)^{th} direction (e.g., the +Z direction in FIG. 9), a force may act to lift the first region of the reinforcement member 560 that does not overlap the connector 570 (e.g., the region of the reinforcement member 560 located between the first edge 560a and the first side surface 570a in FIG. 9) and the first portion 551 coupled to the same, in the (3-2)^{th} direction (e.g., the −Z direction in FIG. 9). At this time, the support member 590 may be maintained in the state of being fixed to the first printed circuit board 541 by the second adhesive member 582, and the first adhesive member 581 may restrict the first region of the reinforcement member 560 and the first portion 551 coupled to the same from being lifted. Accordingly, the flexible printed circuit board 550 and the first portion 551 of the flexible printed circuit board 550 may be restricted from being separated from the connector 570.

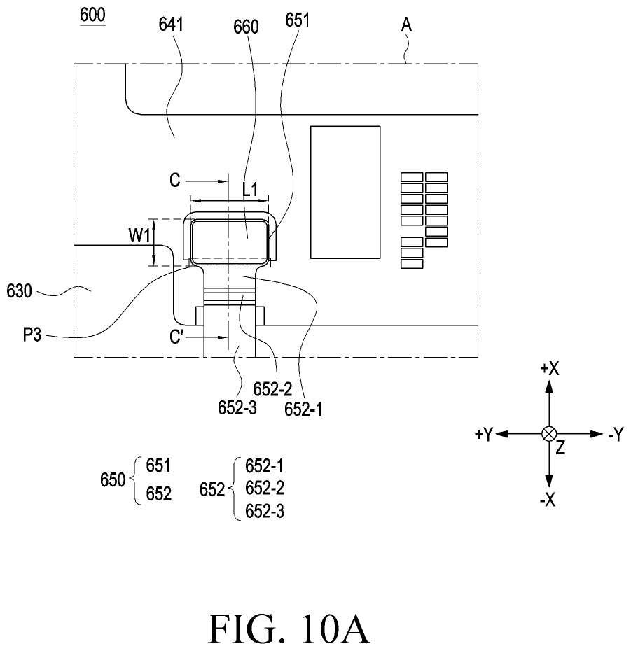

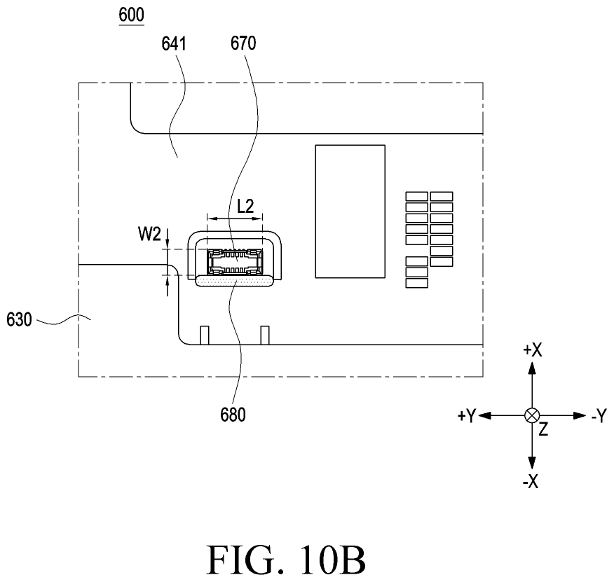

FIG. 10A is a view illustrating in the state in which a flexible printed circuit board is coupled to a printed circuit board of an electronic device according to various embodiments of the disclosure. FIG. 10A is still another enlarged view of portion A in FIG. 5.

Referring to FIG. 10A, an electronic device 600 (e.g., the electronic device 400 in FIG. 5) may include a display 630, a first printed circuit board 641, a flexible printed circuit board 650, and/or a reinforcement member 660.

The configuration of the display 630, the first printed circuit board 641, and/or the flexible printed circuit board 650 of FIG. 10A may be wholly or partly the same as the configuration of the display 430, the first printed circuit board 441, and/or the flexible printed circuit board 450 of FIG. 5.

According to various embodiments, the flexible printed circuit board 650 may include a first surface 650S1 and a second surface 650S2 opposite to the first surface 650S1. According to an embodiment, the first surface 650S1 of the flexible printed circuit board 650 may be the surface facing the display 630, and the second surface 650S2 of the flexible printed circuit board 650 may be the surface facing a battery (not illustrated) (e.g., the battery 350 in FIG. 4) and/or the first support member (not illustrated) (e.g., the first support member 312 in FIG. 4). According to an embodiment, the flexible printed circuit board 650 may be connected, in at least a portion of the first surface 650S1 thereof, to the first printed circuit board 641 via a connector (not illustrated) (e.g., the connector 670 in FIG. 10B and/or FIG. 11).

According to various embodiments, the flexible printed circuit board 650 may include a first portion 651 and a second portion 652 extending from the first portion 651 toward the second printed circuit board (not illustrated) (e.g., the second printed circuit board 442 in FIG. 5).

According to various embodiments, the first portion 651 of the flexible printed circuit board 650 may be configured to be connected to the first printed circuit board 641 via the connector (not illustrated) (e.g., the connector 670 in FIG. 10B and/or FIG. 11).

According to various embodiments, the first portion 651 of the flexible printed circuit board 650 may have a first width W1 in a first direction (e.g., the X-axis direction in FIG. 10A), and a first length L1 in a second direction (e.g., the Y-axis direction in FIG. 10A) perpendicular to the first direction (e.g., the X-axis direction in FIG. 10A). According to an embodiment, the first width W1 may be smaller than the first length L1. According to some embodiments (not illustrated), the first width W1 may be substantially equal to or larger than the first length L1.

According to various embodiments, at least a portion of the second portion 652 of the flexible printed circuit board 650 may be configured to be connected to the second printed circuit board (not illustrated) (e.g., the second printed circuit board 442 in FIG. 4).

According to an embodiment, the second portion 652 of the flexible printed circuit board 650 may include a (2-1)^{th} portion 652-1 coupled and/or connected to the first portion 651, a (2-2)^{th} portion 652-2 extending from the (2-1)^{th} portion 652-1, and/or a (2-3)^{th} portion 652-3 extending from the (2-2)^{th} portion 652-2. According to an embodiment, the lengths of the (2-1)^{th} portion 652-1 (minimum length of (2-1)^{th} portion 652-1), the (2-2)^{th} portion 652-2, and the (2-3)^{th} portion 652-3 in a second direction (e.g., the Y-axis direction in FIG. 10A) may be substantially equal to each other.

According to an embodiment, the first surface 650S1 of the flexible printed circuit board 650 may be defined and/or interpreted as the surface facing the display 630 in the first portion 651 and the second portion 652, and the second surface 650S2 of the flexible printed circuit board 650 may be defined and/or interpreted as a surface opposite to the first surface 650S1 in the first portion 651 and the second portion 652.

According to various embodiments, the electronic device 600 may include a reinforcement member (stiffener) 660 coupled to the second surface 650S2 of the flexible printed circuit board 650. According to an embodiment, the reinforcement member 660 may be coupled to the second surface 650S2 of the first portion 651. According to an embodiment, the reinforcement member 660 may be configured to cover the first portion 651 of the flexible printed circuit board 650, and the reinforcement member 660 may restrict external shock from being directly transferred to the first portion 651 of the flexible printed circuit board 650.

According to various embodiments, the electronic device 600 may further include a support structure including a support member (not illustrated) (e.g., the support member 690 in FIG. 11) and an adhesive member (not illustrated) (e.g., the adhesive member 680 in FIG. 10B and/or FIG. 11).

According to various embodiments, the support structure (not illustrated) may be disposed between the first surface 650S1 of the flexible printed circuit board 650 and the first printed circuit board 641. According to an embodiment, the support structure (not illustrated) may be disposed in a third space P3 located at a position where the flexible printed circuit board 650 and the first printed circuit board 641 are spaced apart from each other. According to an embodiment, the third space P3 may be a space between at least a portion of the first portion 651 and the first printed circuit board 641.

FIG. 10B is a view illustrating the printed circuit board and a connector of the electronic device according to various embodiments of the disclosure. FIG. 10B is a view illustrating the state in which a flexible printed circuit board is removed from the printed circuit board in the electronic device according to various embodiments of the disclosure.

Referring to FIG. 10B, an electronic device 600 (e.g., the electronic device 600 in FIG. 10A) may include a first printed circuit board 641, a display 630, a connector 670, and an adhesive member 680.

The configuration of the first printed circuit board 641 and/or the display 630 of FIG. 10B may be wholly or partly the same as the configuration of the first printed circuit board 641 and/or the display 630 of FIG. 10A.

According to various embodiments, the electronic device 600 may include a connector 670 configured to connect the first printed circuit board 641 and a flexible printed circuit board (not illustrated) (e.g., the flexible printed circuit board 650 in FIG. 10A).

According to various embodiments, the connector 670 may have a second width W2 in a first direction (e.g., the X-axis direction in FIG. 10B), and a second length L2 in a second direction (e.g., the Y-axis direction in FIG. 10B). According to an embodiment, a first width (not illustrated) (e.g., the first width W1 in FIG. 10A) of a first portion (not illustrated) (e.g., the first portion 651 in FIG. 10A) of a flexible printed circuit board (not illustrated) (e.g., the flexible printed circuit board 650 in FIG. 10A) may be larger than the second width W2 of the connector 670.

According to various embodiments, the adhesive member 680 may be disposed between the first printed circuit board 641 and a flexible printed circuit board (not illustrated) (e.g., the flexible printed circuit board 650 in FIG. 10A). According to an embodiment, the adhesive member 680 may be configured to bond the first printed circuit board 641 and the flexible printed circuit board (not illustrated) to each other, and may be disposed in a third space (not illustrated) (e.g., the third space P3 in FIG. 10A). In an embodiment, the adhesive member 680 may be double-sided tape.

FIG. 11 is a cross-sectional view taken along line C-C′ in FIG. 10A according to various embodiments of the disclosure.

Referring to FIG. 11, an electronic device 600 (e.g., the electronic device 600 in FIG. 10A and/or FIG. 10B) may include a display 630, an electromagnetic induction panel 635, a first printed circuit board 641, a flexible printed circuit board 650, a reinforcement member 660, a connector 670, an adhesive member 680, and a support member 690.

The configuration of the display 630 and/or the first printed circuit board 641 in FIG. 11 may be wholly or partly the same as the configuration of the display 630 and/or the first printed circuit board 641 in FIG. 10A and/or FIG. 10B. The configuration of the flexible printed circuit board 650 and/or the reinforcement member 660 of FIG. 11 may be wholly or partly the same as the configuration of the flexible printed circuit board 650 and/or the reinforcement member 660 of FIG. 10A. The configuration of the adhesive member 680 of FIG. 11 may be wholly or partly the same as that of the adhesive member 680 of FIG. 10B. The configuration of the electromagnetic induction panel 635 of FIG. 11 may be wholly or partly the same as that of the electromagnetic induction panel 370 of FIG. 4.

According to various embodiments, the electromagnetic induction panel 635 may be disposed between the first printed circuit board 641 and the display 630. According to some embodiments (not illustrated), the electromagnetic induction panel 635 may be disposed to face the first printed circuit board 641 with the display 630 interposed therebetween.

According to various embodiments, the connector 670 may be configured to connect at least a portion of the first surface 650S1 (e.g., the surface oriented in the +Z direction in FIG. 11) of the flexible printed circuit board 650 and the first printed circuit board 641. According to an embodiment, the connector 670 may be configured to electrically connect the first portion 651 of the flexible printed circuit board 650 and the first printed circuit board 641. In an embodiment, a plug connector may be disposed on the first portion 651 of the flexible printed circuit board 650, and the connector 670 may include a receptacle connector to be fastened to the plug connector disposed on the first portion 651 of the flexible printed circuit board 650. In another embodiment, the connector 670 may include a board-to-board (B-to-B) connector.

According to various embodiments, the reinforcement member 660 may be coupled to the second surface 650S2 (e.g., the surface oriented in the −Z direction in FIG. 11) of the flexible printed circuit board 650. According to an embodiment, the reinforcement member 660 may be coupled to the first portion 651 of the flexible printed circuit board 650, and may be disposed to face the connector 670 with the flexible printed circuit board 650 interposed therebetween.

According to various embodiments, the reinforcement member 660 may extend in a first direction (e.g., the X-axis direction in FIG. 11) including a (1-1)^{th} direction (e.g., the +X direction in FIG. 11) and a (1-2)^{th} direction (e.g., the −X direction in FIG. 11) opposite to the (1-1)^{th} direction (e.g., +X-axis direction in FIG. 11). According to an embodiment, the reinforcement member 660 may include a first edge 660a oriented in the (1-1)^{th} direction (e.g., the +X direction in FIG. 11) and a second edge 660b oriented in the (1-2)^{th} direction (e.g., the −X direction in FIG. 11).

According to various embodiments, the flexible printed circuit board 650 may include a first portion 651 configured to be connected to the connector 670, and a second portion 652 extending from the first portion 651 toward the second printed circuit board (not illustrated) (e.g., the second printed circuit board 642 in FIG. 5). According to an embodiment, the second portion 652 may include a (2-1)^{th} portion 652-1 extending from the first portion 651, a (2-2)^{th} portion 652-2 extending from the (2-1)^{th} portion 652-1 obliquely to approach the display 630, and a (2-3)^{th} portion 652-3 extending from the (2-2)^{th} portion 652-2 substantially in parallel to the display 630. According to an embodiment, the second portion 652 of the flexible printed circuit board 650 may be electrically and/or physically connected, in at least a portion (e.g., the (2-3)^{th} portion 652-3), to the second printed circuit board (not illustrated) (e.g., the second printed circuit board 642 in FIG. 5).

According to various embodiments, the connector 670 may include a first side surface 670a oriented in the (1-1)^{th} direction (e.g., the +X direction in in FIG. 11) and a second side surface 670b oriented in the (1-2)^{th} direction (e.g., the −X direction in FIG. 11). According to various embodiments, at least one of the first side surface 670a and the second side surface 670b may be disposed between the first edge 660a and the second edge 660b with reference to the first direction (e.g., the X-axis direction in FIG. 11). According to an embodiment, the first side surface 670a and the second side surface 670b may be disposed between the first edge 660a and the second edge 660b.

According to various embodiments, the support member 690 may be disposed between a first surface 650S1 (e.g., the surface oriented in the −Z direction in FIG. 11) of the flexible printed circuit board 650 and the first printed circuit board 641. According to an embodiment, at least a portion of the support member 690 may be disposed to face the reinforcement member 660 with the flexible printed circuit board 650 interposed therebetween. According to an embodiment, the support member 690 may include at least one of a Poron member, a silicone member, a rubber member, or a sponge member (i.e., insulating material).

According to various embodiments, the adhesive member 680 may include a first adhesive member 681, a second adhesive member 682, and/or a third adhesive member 683. According to an embodiment, the first adhesive member 681 may be configured to bond the support member 690 and the first surface 650S1 (e.g., the surface oriented in the +Z direction in FIG. 11) of the flexible printed circuit board 650. In an embodiment, the first adhesive member 681 may include at least one of adhesive tape or double-sided tape. According to an embodiment, the second adhesive member 682 may be configured to bond the support member 690 and the first printed circuit board 641 to each other. In an embodiment, the second adhesive member 682 may include at least one of adhesive tape or double-sided tape. According to an embodiment, the third adhesive member 683 may be configured to bond the support member 690 and the connector 670 to each other. In an embodiment, the third adhesive member 683 may include at least one of adhesive tape or double-sided tape.

According to an embodiment, the first portion 651 may have a first thickness in a third direction (e.g., the Z-axis direction in FIG. 11) perpendicular to the first direction (e.g., the X-axis direction in FIG. 11) and the second direction (e.g., the Y-axis direction in FIG. 11), and the connector 670 may have a second thickness in the third direction (e.g., the Z-axis direction in FIG. 11). In an embodiment, the second thickness may be larger than the first thickness.

According to an embodiment, sum of the thicknesses of the support member 690, the first adhesive member 681, and the second adhesive member 682 in the third direction (e.g., the Z-axis direction in FIG. 11) may be substantially equal to the second thickness.

According to various embodiments, at least a portion of the support member 690 may be disposed between the second edge 660b and the second side surface 670b. According to an embodiment, the support member 690 may include a third side surface 690a oriented in the (1-1)^{th} direction (e.g., the +X direction in FIG. 11) and configured to be connected to the second side surface 670b and a fourth side surface 690b oriented in the (1-2)^{th} direction (e.g., the −X direction in FIG. 11). According to an embodiment, the third side surface 690a may be disposed between the second edge 660b and the second side surface 670b, and the fourth side surface 690b may be disposed between a region where the first portion 651 and the (2-1)^{th} portion 652-1 are connected and the first printed circuit board 641. For example, the fourth side surface 690b may be disposed on substantially the same plane as one end edge (e.g., the edge oriented in the −X direction in FIG. 11) of the first portion 651.

According to an embodiment, the first adhesive member 681 may be configured to bond at least a portion of one surface (e.g., the surface oriented in the −Z direction in FIG. 11) of the support member 690 to the first portion 651.

According to an embodiment, the second adhesive member 682 may be configured to bond at least a portion of the other surface (e.g., the surface oriented in the +Z direction in FIG. 11) of the support member 690 to the first printed circuit board 641.

According to an embodiment, the third adhesive member 683 may be configured to bond at least a portion of the third side surface 690a of the support member 690 to the second side surface 670b of the connector 670.

According to an embodiment, the support member 690 may be disposed between the connector 670 and a second printed circuit board (not illustrated) (e.g., the second printed circuit board 442 in FIG. 5). According to an embodiment, the third side surface 690a of the support member 690 may be disposed to face the connector 670. According to an embodiment, the fourth side surface 690b of the support member 690 may be disposed to face the second printed circuit board (not illustrated) (e.g., the second printed circuit board 442 in FIG. 5).

According to various embodiments, the support structure including the support member 690 and the adhesive member 680 may restrict the flexible printed circuit board 650 from being separated and/or detached from the connector 670.

For example, when an external force acts on a first region of the reinforcement member 660 that does not overlap the connector 670 (e.g., the region of the reinforcement member 660 located between the first edge 660a and the first side surface 670a in FIG. 11) in a (3-1)^{th} direction (e.g., the +Z direction in FIG. 11), a force may act to lift a second region of the reinforcement member 660 that does not overlap the connector 670 (e.g., the region of the reinforcement member 660 located between the second edge 660b and the second side surface 670b in FIG. 11) and the first portion 651 coupled to the same, in the (3-2)^{th} direction (e.g., the −Z direction in FIG. 11). At this time, the support member 690 may be maintained in the state of being fixed to the first printed circuit board 641 and the connector 670 by the second adhesive member 682 and the third adhesive member 683, and the first adhesive member 681 may restrict the second region of the reinforcement member 660 and the first portion 651 coupled to the same from being lifted. Accordingly, the flexible printed circuit board 650 and the first portion 651 of the flexible printed circuit board 650 may be restricted from being separated from the connector 670.

For example, when an external force acts on the second region of the reinforcement member 660 that does not overlap the connector 670 (e.g., the region of the reinforcement member 660 located between the second edge 660b and the second side surface 670b in FIG. 11) in the (3-1)^{th} direction (e.g., the +Z direction in FIG. 11), a force may act to lift the first region of the reinforcement member 660 that does not overlap the connector 670 (e.g., the region of the reinforcement member 660 located between the first edge 660a and the first side surface 670a in FIG. 11) and the first portion 651 coupled to the same, in the (3-2)^{th} direction (e.g., the −Z direction in FIG. 11). At this time, the support member 690 may restrict the first region of the reinforcement member 660 and the first portion 651 coupled to the same from being lifted by supporting the second region of the reinforcement member 660 and the first portion 651 coupled to the same being pressed in the (3-1)^{th} direction (e.g., the +Z direction in FIG. 11). Accordingly, the first portion 651 of the flexible printed circuit board 650 may be restricted from being separated from the connector 670.

According to various embodiments of the disclosure, an electronic device (e.g., the electronic device 101 in FIG. 1, the electronic device 300 in FIG. 4, or the electronic device 400 in FIG. 5) may include a housing (e.g., the housing 310 in FIG. 4), a display (e.g., the display 330 in FIG. 4 or the display 430 in FIG. 5) disposed in the housing, a first printed circuit board (e.g., the first printed circuit board 441 in FIG. 5) disposed within the housing, a flexible printed circuit board (e.g., the flexible printed circuit board 450 in FIG. 5) disposed within the housing, where the flexible printed circuit board includes a first surface and a second surface opposite to the first surface (e.g., the first surface 450S1 and the second surface 450S2 in FIG. 7), a connector (e.g., the connector 470 in FIG. 6B and/or FIG. 7) configured to connect at least a portion of the first surface of the flexible printed circuit board and the first printed circuit board, a reinforcement member (e.g., the reinforcement member 460 in FIG. 6A and/or FIG. 7) coupled to the second surface of the flexible printed circuit board, where at least a portion of the reinforcement member is disposed to face the connector with the flexible printed circuit board interposed therebetween, a support member (e.g., the support member 460 in FIG. 7) disposed between the first surface of the flexible printed circuit board and the first printed circuit board, where at least a portion of the support member is disposed to face the reinforcement member with the flexible printed circuit board interposed therebetween, a first adhesive member (e.g., the first adhesive member 481 in FIG. 7) configured to adhere the support member and the first surface of the flexible printed circuit board to each other, and a second adhesive member (e.g., the second adhesive member 482 in FIG. 7) configured to adhere the support member and the first printed circuit board to each other.

According to various embodiments, the electronic device may further include a second printed circuit board (e.g., the second printed circuit board 442 in FIG. 5) disposed within the housing and spaced apart from the first printed circuit board. The flexible printed circuit board may include a first portion (e.g., the first portion 451 in FIGS. 6A and/or 7) configured to be connected to the connector, and a second portion (e.g., the second portion 452 in FIG. 6A and/or FIG. 7) extending from the first portion toward the second printed circuit board. At least a portion of the second portion may be configured to be connected to the second printed circuit board.

According to various embodiments, the first portion may have a first width (e.g., the first width W1 in FIG. 6A) in a first direction (e.g., the X-axis direction in FIGS. 6A to 7), a first length (e.g., the first length L1 in FIG. 6A) in a second direction (e.g., the Y-axis direction in FIGS. 6A to 7) perpendicular to the first direction, and a first thickness in a third direction (e.g., the Z-axis direction in FIGS. 6A to 7) perpendicular to the first direction and the second direction. The connector may have a second width (e.g., the second width W2 in FIG. 6B) in the first direction, a second length (e.g., the second length L2 in FIG. 6B) in the second direction, and a second thickness in the third direction, and the first width may be larger than the second width.

According to various embodiments, sum of the thicknesses of the support member, the first adhesive member, and the second adhesive member in the third direction may be substantially equal to the second thickness.

According to various embodiments, the flexible printed circuit board may include a first portion configured to be coupled to the connector and the reinforcement member, and a second portion extending from the first portion. The reinforcement member may extend in a first direction (e.g., the X-axis direction in FIG. 7) including a (1-1)^{th} direction (e.g., the +X direction in FIG. 7) and a (1-2)^{th} direction (e.g., the −X direction in FIG. 7) opposite to the (1-1)^{th} direction and include a first edge (e.g., the first edge 460a in FIG. 7) oriented in the (1-1)^{th} direction and a second edge oriented in the (1-2)^{th} direction. The connector may include a first side surface (e.g., the first side surface 470a in FIG. 7) oriented in the (1-1)^{th} direction, and a second side surface (e.g., the second side surface 470b in FIG. 7) oriented in the (1-2)^{th} direction. At least one of the first side surface and the second side surface may be disposed between the first edge and the second edge with reference to the first direction (e.g., the X-axis direction in FIG. 7).

According to various embodiments, at least a portion of the support member (e.g., the support member 490 in FIG. 7 or the support member 690 in FIG. 11) may be disposed between the second edge (e.g., the second edge 460b in FIG. 7 or the second edge 660b in FIG. 11) and the second side surface (e.g., the second side surface 470b in FIG. 7 or the second side surface 670b in FIG. 11) with reference to the first direction (e.g., the X-axis direction in FIG. 7 or the X-axis direction in FIG. 11).

According to various embodiments, the support member (e.g., the support member 490 in FIG. 7) may include a third side surface (e.g., the third side surface 490a in FIG. 7) oriented in the (1-1)^{th} direction and spaced apart from the second side surface, and a fourth side surface (e.g., the fourth side surface 490b in FIG. 7) oriented in the (1-2)^{th} direction. The fourth side surface may be disposed between the second portion and the first printed circuit board, and the first adhesive member may be configured to adhere the support member to the first portion and the second portion.

According to various embodiments, the support member (e.g., the support member 690 in FIG. 11) may include a third side surface (e.g., the third side surface 690a in FIG. 11) oriented in the (1-1)^{th} direction and configured to face the second side surface (e.g., the second side surface 670b in FIG. 11) and a fourth side surface (e.g., the fourth side surface 690b in FIG. 11) oriented in the (1-2)^{th} direction. The first adhesive member may be configured to adhere the support member to the first portion (e.g., the first portion 651 in FIG. 11).

According to various embodiments, the electronic device may further include a third adhesive member (e.g., the third adhesive member 683 in FIG. 11) configured to adhere the second side and the third side to each other.

According to various embodiments, at least a portion of the support member (e.g., the support member 590 in FIG. 9) may be disposed between the first edge (e.g., the first edge 560a in FIG. 9) and the first side surface (e.g., the first side surface 570a in FIG. 9).

According to various embodiments, the support member may include a third side surface (e.g., the third side surface 590a in FIG. 9) oriented in the (1-1)^{th} direction, and a fourth side surface (e.g., the fourth side surface 590b in FIG. 9) oriented in the (1-2)^{th} direction and disposed to face the first side surface. The fourth side surface may be disposed between the first edge and the first side surface.

According to various embodiments, the electronic device may further include a second printed circuit board (e.g., the second printed circuit board 442 in FIG. 5) spaced apart from the first printed circuit board. The display may further include a touch panel electrically connected to the first printed circuit board and a second printed circuit board electrically connected to the second printed circuit board. The flexible printed circuit board may include a first portion configured to be electrically connected to the first printed circuit board, and a second portion electrically connected to the second printed circuit board.

According to various embodiments, the support member (e.g., the support member 490 in FIG. 7 or the support member 690 in FIG. 11) may include a third side surface (e.g., the third side surface 490a in FIG. 7 or the third side surface 690a in FIG. 11) oriented in the (1-1)^{th} direction (e.g., the +X direction in FIG. 7 or the +X direction in FIG. 11) and a fourth side surface (e.g., the fourth side surface 490b in FIG. 7 or the fourth side surface 690b in FIG. 11) oriented in the (1-2)^{th} direction (e.g., the −X direction in FIG. 7 or the −X direction in FIG. 11) opposite to the (1-1)^{th} direction. The third side surface may be disposed to face the connector (e.g., the connector 470 in FIG. 7 or the connector 670 in FIG. 11), and the fourth side surface may be disposed to face the second printed circuit board.

According to various embodiments, the connector (e.g., the connector 570 in FIG. 9) may include a first side surface (e.g., the first side surface 570a in FIG. 9) oriented in a (1-1)^{th} direction (e.g., the +X direction in FIG. 9) and a second side surface (e.g., the second side surface 570b in FIG. 9) oriented in a (1-2)^{th} direction (e.g., the −X direction in FIG. 9), which is opposite to the (1-1)^{th} direction. The first side surface may be disposed to face the support member (e.g., the support member 590 in FIG. 9), and the second side surface may be disposed to face the second printed circuit board.

According to various embodiments, the electronic device may further include a third adhesive member (e.g., the third adhesive member 683 in FIG. 11) configured to adhere the connector and the support member to each other.

According to various embodiments of the disclosure, an electronic device (e.g., the electronic device 101 in FIG. 1, the electronic device 300 in FIG. 4, or the electronic device 400 in FIG. 5) may include a housing (e.g., the housing 310 in FIG. 4), a display (e.g., the display 330 in FIG. 4 or the display 430 in FIG. 5) disposed in the housing and including a touch panel and a display panel, a first printed circuit board (e.g., the first printed circuit board 441 in FIG. 5) disposed within the housing and electrically connected to the touch sensor, a second printed circuit board (e.g., the second printed circuit board 442 in FIG. 5) spaced apart from the first printed circuit board and electrically connected to the display panel, a flexible printed circuit board (e.g., the flexible printed circuit board 450 in FIG. 5) disposed within the housing and including a first portion (e.g., the first portion 451 in FIG. 7) electrically connected to the first printed circuit board, and a second portion (e.g., the second portion 452 in FIG. 7) extending from the first portion and electrically connected to the second printed circuit board, a connector (e.g., the connector 470 in FIG. 7) configured to connect the first printed circuit board and the first portion, a reinforcement member (e.g., the reinforcement member 460 in FIG. 7) coupled to the first portion, where at least a portion of the reinforcement member is disposed to face the connector with the first portion interposed therebetween, and a support member (e.g., the support member 490 in FIG. 7) disposed between the flexible printed circuit board and the first printed circuit board, where at least a portion of the support member is disposed to face the reinforcement member with the first portion interposed therebetween.

The electronic device may further include a first adhesive member (e.g., the first adhesive member 481 in FIG. 7) configured to adhere the support member and the first surface of the flexible printed circuit board to each other, and a second adhesive member (e.g., the second adhesive member 482 in FIG. 7) configured to adhere the support member and the first printed circuit board to each other.

According to various embodiments, the support member may be configured to support at least a portion of the first portion.

According to various embodiments, the first adhesive member may be configured to fix the flexible printed circuit board to the support member, and the second adhesive member may be configured to fix the support member to the first printed circuit board.

According to various embodiments, the electronic device may further include a third adhesive member (e.g., the third adhesive member 683 in FIG. 11) configured to adhere the support member and the connector to each other.

According to various embodiments of the disclosure, a support structure of a connection circuit board (e.g., the flexible printed circuit board 450 in FIG. 5 or the flexible printed circuit board 450 in FIG. 7) may include a first printed circuit board (e.g., the first printed circuit board 441 in FIG. 5 or the first printed circuit board 441 in FIG. 7), a connector (e.g., the connector 470 in FIG. 7) coupled to at least a portion of the first printed circuit board, a flexible printed circuit board (e.g., the flexible printed circuit board 450 in FIG. 5 or the flexible printed circuit board 450 in FIG. 7) including a first portion (e.g., the first portion 451 in FIG. 7) coupled to the connector and a second portion (e.g., the second portion 452 in FIG. 7) extending from the first portion, a reinforcement member (e.g., the reinforcement member 460 in FIG. 7) coupled to the first portion, where at least a portion of the reinforcement member is disposed to face the connector with the first portion interposed therebetween, a support member (e.g., the support member 490 in FIG. 7) disposed between the first portion and the first printed circuit board, a first adhesive member (e.g., the first adhesive member 481 in FIG. 7) configured to adhere the support member and the first portion to each other, and a second adhesive member (e.g., the second adhesive member 482 in FIG. 7) configured to adhere the support member and the first printed circuit board to each other.

According to various embodiments of the disclosure, a support structure of a connection circuit board (e.g., the flexible printed circuit board 450 in FIG. 5 or the flexible printed circuit board 450 in FIG. 7) may include a printed circuit board (e.g., the first printed circuit board 441 in FIG. 5 or the first printed circuit board 441 in FIG. 7), a connector (e.g., the connector 470 in FIG. 7) disposed on and electrically coupled to the printed circuit board, a flexible printed circuit board (e.g., the flexible printed circuit board 450 in FIG. 5 or the flexible printed circuit board 450 in FIG. 7) disposed on and electrically coupled to the connector, a reinforcement member (e.g., the reinforcement member 460 in FIG. 7) disposed on and coupled to the flexible printed circuit board, where the reinforcement member may cover an entirety of the connector in a plan view, an area of the reinforcement member may be greater than an area of the connector in the plan view, and the flexible printed circuit board may be disposed between the connector and the reinforcement member, and a support member (e.g., the support member 490 in FIG. 7) disposed between the flexible printed circuit board and the printed circuit board, where the support member may partially overlap the reinforcement member in the plan view.

As used herein, the “plan view” is a view in a normal direction (i.e., Z-axis direction) of a major surface (X-Y plane) of the printed circuit board (e.g., the flexible printed circuit board 450 in FIG. 5 or the flexible printed circuit board 450 in FIG. 7). In the foregoing detailed description of this disclosure, specific embodiments have been described, but it will be evident to a person ordinarily skilled in the art that various modifications can be made without departing from the scope of the disclosure.

What is claimed is:

1. An electronic device comprising:
a housing;
a display disposed in the housing;
a first printed circuit board disposed within the housing;
a flexible printed circuit board disposed within the housing, wherein the flexible printed circuit board includes a first surface and a second surface opposite to the first surface;
a connector configured to connect at least a portion of the first surface of the flexible printed circuit board and the first printed circuit board;
a reinforcement member coupled to the second surface of the flexible printed circuit board, wherein at least a portion of the reinforcement member is disposed to face the connector with the flexible printed circuit board interposed therebetween;
a support member disposed between the first surface of the flexible printed circuit board and the first printed circuit board, wherein at least a portion of the support member is disposed to face the reinforcement member with the flexible printed circuit board interposed therebetween;
a first adhesive member configured to adhere the support member and the first surface of the flexible printed circuit board to each other; and
a second adhesive member configured to adhere the support member and the first printed circuit board to each other.

2. The electronic device of claim 1, further comprising:
a second printed circuit board disposed within the housing and spaced apart from the first printed circuit board,
wherein the flexible printed circuit board further includes a first portion configured to be connected to the connector and a second portion extending from the first portion toward the second printed circuit board, and
wherein at least a portion of the second portion is configured to be electrically connected to the second printed circuit board.

3. The electronic device of claim 2, wherein the first portion has a first width in a first direction, a first length in a second direction perpendicular to the first direction, and a first thickness in a third direction perpendicular to the first direction and the second direction,
wherein the connector has a second width in the first direction, a second length in the second direction, and a second thickness in the third direction, and
wherein the first width is larger than the second width.

4. The electronic device of claim 3, wherein sum of thicknesses of the support member, the first adhesive member, and the second adhesive member in the third direction are substantially equal to the second thickness.

5. The electronic device of claim 1, wherein the flexible printed circuit board further includes a first portion configured to be coupled to the connector and the reinforcement member, and a second portion extending from the first portion,
wherein the reinforcement member extends in a first direction including a (1-1)^{th} direction and a (1-2)^{th} direction opposite to the (1-1)^{th} direction and includes a first edge oriented in the (1-1)^{th} direction and a second edge oriented in the (1-2)^{th} direction,
wherein the connector includes a first side surface oriented in the (1-1)^{th} direction and a second side surface oriented in the (1-2)^{th} direction, and
wherein at least one of the first side surface and the second side surface is disposed between the first edge and the second edge with reference to the first direction.

6. The electronic device of claim 5, wherein at least a portion of the support member is disposed between the second edge and the second side surface with reference to the first direction.

7. The electronic device of claim 6, wherein the support member includes a third side surface oriented in the (1-1)^{th} direction and spaced apart from the second side surface, and a fourth side surface oriented in the (1-2)^{th} direction,
wherein the fourth side surface is disposed between the second portion and the first printed circuit board, and
wherein the first adhesive member is configured to adhere the support member to the first portion and the second portion.

8. The electronic device of claim 6, wherein the support member includes a third side surface oriented in the (1-1)^{th} direction and configured to face the second side surface, and a fourth side surface oriented in the (1-2)^{th} direction, and
wherein the first adhesive member is configured to adhere the support member to the first portion.

9. The electronic device of claim 8, further comprising:
a third adhesive member configured to adhere the second side surface and the third side surface to each other.

10. The electronic device of claim 5, wherein at least a portion of the support member is disposed between the first edge and the first side surface.

11. The electronic device of claim 10, wherein the support member includes a third side surface oriented in the (1-1)^{th} direction and a fourth side surface oriented in the (1-2)^{th} direction and disposed to face the first side surface, and
wherein the fourth side surface is disposed between the first edge and the first side surface.

12. The electronic device of claim 1, further comprising:
a second printed circuit board spaced apart from the first printed circuit board,
wherein the display includes a touch sensor electrically connected to the first printed circuit board and a display panel electrically connected to the second printed circuit board, and
wherein the flexible printed circuit board further includes a first portion electrically connected to the first printed circuit board, and a second portion electrically connected to the second printed circuit board.

13. The electronic device of claim 12, wherein the support member comprises a third side surface oriented in a (1-1)^{th} direction and a fourth side surface oriented in a (1-2)^{th} direction opposite to the (1-1)^{th} direction,
wherein the third side surface is disposed to face the connector, and
wherein the fourth side surface is disposed to face the second printed circuit board.

14. The electronic device of claim 12, wherein the connector comprises a first side surface oriented in a (1-1)^{th} direction and a second side surface oriented in the (1-2)^{th} direction opposite to the (1-1)^{th} direction,
wherein the first side surface is disposed to face the support member, and
wherein the second side surface is disposed to face the second printed circuit board.

15. The electronic device of claim 1, further comprising:
a third adhesive member configured to adhere the connector and the support member to each other.

16. a support structure of a connection circuit board comprising:
a printed circuit board;
a connector disposed on and electrically coupled to the printed circuit board;
a flexible printed circuit board disposed on and electrically coupled to the connector;
a reinforcement member disposed on and coupled to the flexible printed circuit board, wherein the reinforcement member covers an entirety of the connector in a plan view, an area of the reinforcement member is greater than an area of the connector in the plan view, and the flexible printed circuit board is disposed between the connector and the reinforcement member; and
a support member disposed between the flexible printed circuit board and the printed circuit board, wherein the support member partially overlaps the reinforcement member in the plan view.

17. The support structure of claim 16, further comprising:
a first adhesive member configured to adhere the support member and a first surface of the flexible printed circuit board to each other; and
a second adhesive member configured to adhere to support member and the printed circuit board.

18. The support structure of claim 17, wherein the support member is configured to support at least a portion of a first portion of the flexible printed circuit board, and
wherein the first portion of the flexible printed circuit board is electrically connected to the printed circuit board.

19. The support structure of claim 18, wherein the first adhesive member is configured to fix the flexible printed circuit board to the support member, and
wherein the second adhesive member is configured to fix the support member to the printed circuit board.

20. The support structure of claim 16. further comprising a third adhesive member configured to adhere the support member and the connector to each other.
